(19) United States
(12) Patent Application Publication
(10) Pub. No.: US 2014/0063972 A1
(43) Pub. Date: Mar. 6, 2014

(54) SEMICONDUCTOR STORAGE DEVICE

(71) Applicant: KABUSHIKI KAISHA TOSHIBA, Tokyo (JP)

(72) Inventor: Takashi MAEDA, Kanagawa (JP)

(73) Assignee: Kabushiki Kaisha Toshiba, Tokyo (JP)

(21) Appl. No.: 13/783,365

(22) Filed: Mar. 3, 2013

(30) Foreign Application Priority Data
Aug. 28, 2012 (JP) 2012-187877

(51) Int. Cl. G11C 16/34

(52) U.S. Cl. CPC G11C 16/3459
USPC 365/185.22

(57) ABSTRACT

According to one embodiment, a storage device includes multiple cell transistors connected in series, a first selecting transistor connected between a first end of the connected cell transistors and a first line, and a second selecting transistor connected between a second end of the connected cell transistors and a second line. Writing to the multiple cell transistors is includes the following operations: a first voltage is applied to a gate of the first selecting transistor, and a second voltage lower than the first voltage is applied to the gate of the second selecting transistor; a verify voltage is applied to a selected word line, and a pass voltage is applied to non-selected word lines. A third voltage lower than the first voltage is then applied to the gate of the first selecting transistor, and a program voltage is applied to the selected word line.

### CROSS-REFERENCE TO RELATED APPLICATION

This application is based upon and claims the benefit of priority from Japanese Patent Application No. 2012-187877, filed Aug. 28, 2012; the entire contents of which are incorporated herein by reference.

### FIELD

Embodiments described herein relates to a semiconductor storage device.

### BACKGROUND

Writing data to a NAND-type flash memory generally includes writing data to the memory cells as the write object, reading the written data to verify the writing process, and rewriting to the memory cells which did not successfully complete the previous writing step as detected by the corresponding reading of the writing result. By repeatedly carrying out this set of writing and reading, the threshold voltage of the memory cells is pulled up to the prescribed (written) level.

### DESCRIPTION OF THE DRAWINGS

FIG. 1 is a block diagram illustrating an example of the overall constitution of the semiconductor storage device according to Embodiment 1.

FIG. 2 is a circuit diagram illustrating the memory cell array.

FIG. 3 is a cross-sectional view illustrating the memory cell array.

FIG. 4 is an oblique view illustrating the memory cell array.

FIG. 5 is a cross-sectional view illustrating the memory cell array.

FIG. 6 is a circuit diagram illustrating the memory cell array.

FIG. 7 is a diagram illustrating a state during write processing in Embodiment 1.

FIG. 8 is a diagram succeeding FIG. 7 in illustrating additional states.

FIG. 9 is a time chart illustrating the voltage during write according to Embodiment 1.

FIG. 10 is a diagram illustrating a side surface of the principle of write according to Embodiment 1.

FIG. 11 is a diagram illustrating another state during the writing process according to Embodiment 1.

FIG. 12 is a diagram succeeding FIG. 11 in illustrating an additional state during the writing process.

FIG. 13 is a flow chart illustrating a writing process according to Embodiment 2.

FIG. 14 is a diagram illustrating transition of the cell transistor threshold voltage distribution due to write according to Embodiment 2.

FIG. 15 is a diagram illustrating the state during write according to Embodiment 3.

FIG. 16 is a diagram illustrating the state during write according to Embodiment 4.

FIG. 17 is a time chart illustrating the voltage during write according to Embodiment 4.

FIG. 18 is a diagram illustrating the state during write according to Embodiment 5.

FIG. 19 is a time chart illustrating the voltage during write according to Embodiment 5.

FIG. 20 is a diagram illustrating the state during write according to the second example of Embodiment 5.

FIG. 21 is a flow chart illustrating write according to the third example of Embodiment 5.

FIG. 22 is a diagram illustrating the state during write according to the fourth example of Embodiment 5.

FIG. 23 is a time chart illustrating the voltage during write according to the fourth example of Embodiment 5.

FIG. 24 is a diagram illustrating the state during write according to the fifth example of Embodiment 5.

FIG. 25 is a diagram illustrating the state during write according to the sixth example of Embodiment 5.

FIG. 26 is a diagram illustrating the state during write according to Embodiment 6.

FIG. 27 is a time chart illustrating the voltage during write according to Embodiment 6.

FIG. 28 is a diagram illustrating the state during write according to Embodiment 7.

FIG. 29 is a flow chart illustrating write according to Embodiment 7.

FIG. 30 is a diagram illustrating the state during write according to Embodiment 8.

FIG. 31 is a time chart illustrating the voltage during write according to Embodiment 8.

### DETAILED DESCRIPTION

Embodiments of the present disclosure provide a semiconductor storage device that allows low power consumption and a high speed write.

In general, according to one embodiment, in write of a semiconductor storage device, the written cell transistors and the unwritten cell transistors in the selected page are distinguished from each other by controlling the voltages of the lines connected to the various cell transistors. A semiconductor storage device includes cell transistors connected in series, a first selecting transistor connected to the serially connected cell transistors on a first end, a second selecting transistor connected to the serially connected cell transistors on a second end, a first and second wire respectively connected to first and second selecting transistors. The cell transistors are each connected to a respective word line. The storage device is configured to operate such that the writing process includes applying a first voltage (such as, for example, a positive supply voltage) to a gate of the first selecting transistor, and a second voltage lower than the first voltage (such as, for example, a negative supply voltage) to a gate of the second selecting transistor, then applying a verify voltage to a selected word line, and a pass voltage (inhibit voltage) to non-selected word lines connected to the cell transistors located between the cell transistor connected to the selected word line and the second selecting transistor. Then applying a third voltage lower than the first voltage (such as, for example, a negative supply voltage) to the gate of the first selecting transistor; and applying a program voltage to the selected word line to write data to selected cell transistors.

That is, for a written cell transistor, the bit line connected to it is kept at a low level (e.g., voltage Vss (the negative supply potential)), so that it is set in the program (written) state. On the other hand, for an unwritten cell transistor, the bit line connected to it is driven at a high level (e.g., voltage Vdd (the positive supply potential)), so that it is set in the inhibit state (inhibited for write). The program state and the inhibit state are also adopted in rewrite after the verify step. That is, in rewrite, the cell transistors not reaching the target threshold voltage are set in the program state, while the cell transistors having threshold over the target are set in the inhibit state.

The semiconductor storage device as an embodiment of the present disclosure has a first line, a second line, a memory string and word lines. The memory string includes multiple cell transistors connected in series, a first selecting transistor connected between the first end of the multiple cell transistors and the first line, and a second selecting transistor connected between the second end of the multiple cell transistors and the second line. The word lines are connected to the multiple cell transistors, respectively. Here, write to the multiple cell transistors is carried out as follows: a first voltage is applied to the gate of the first selecting transistor, and a second voltage lower than the first voltage is applied to the gate of the second selecting transistor; a verify voltage is applied to the selected word line, and a pass voltage is applied to the non-selected word lines nearer the side of the second line than the selected word line; a third voltage lower than the first voltage is applied to the gate of the first selecting transistor, and a program voltage is applied to the selected word line.

Distinguishing between the program state and inhibit state exploits the difference in the voltage of the bit lines. Consequently, write of data using the bit line in write operation relates to only one cell transistor connected to the bit line. This is realized by selecting 1 page by selecting one word line.

On the other hand, for the NAND-type flash memory having a three-dimensional structure, such as the NAND-type flash memory using the BiCS (“Bit-Cost Scalable”) technology (hereinafter to be referred to as BiCS memory), the multiple memory strings that share one bit line also share the word line. However, in the write operation, by selecting only one memory string, the write object is only 1 page. Consequently, there is also a latent ability to write parallel with multiple strings that share the bit line by selecting one word line, such possibility is nevertheless not generated from the necessity of control of execution/inhibit of write using the bit line voltage. Because it is necessary to connect only one memory string to one bit line in read for verify during write, similarly, the latent ability of the BiCS memory is not displayed.

In the following, the embodiments will be explained with reference to the drawings. In the following explanation, the same key will be adopted to represent the structural elements having generally the same function and constitution, so repeated explanation will be made only as necessary.

### Embodiment 1

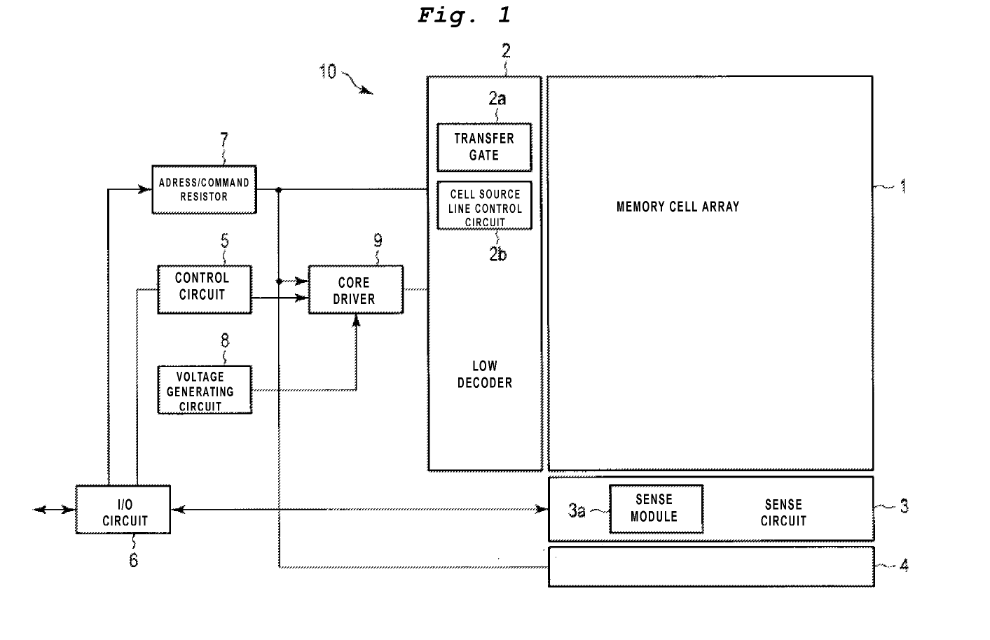

FIG. 1 is a block diagram illustrating an example of the overall constitution of the semiconductor storage device related to Embodiment 1 of the present disclosure. In FIG. 1 and the other drawings, there is no need to distinguish the various functional blocks as that shown in the figure. For example, some functions may be executed by other functional blocks different from those presented below as example for illustration. In addition, each functional block presented as an example may be further divided into finer functional sub-blocks.

As shown in FIG. 1, the semiconductor storage device 10 includes a memory cell array 1, a row decoder 2, a sense circuit 3, a column decoder 4, a controller 5, an input/output circuit 6, an address command register 7, a voltage generator 8, and a core driver 9. The memory cell array 1 includes multiple blocks (memory blocks). Each block includes multiple memory cells (memory cell transistors), word lines WL, bit lines BL, etc. Prescribed multiple memory cells or their storage spaces form a page. The data are read or written in page units, and they are deleted in block units. Details of the memory cell array 1 will be explained later.

The row decoder 2 contains transfer gate 2a and cell source line controller 2b. The row decoder 2 receives the block address signal, etc. from the address command register 7, and it receives the word line control signal and selecting gate control signal from the core driver 9. On the basis of the received block address signal, word line control signal, and selecting gate control signal, the row decoder 2 selects the prescribed block and word line WL. The row decoders 2 may also be arranged on the two sides of the memory cell array 1.

The sense circuit 3 reads the data from the memory cell array 1, and temporarily holds the read data. In addition, the sense circuit 3 receives the write data from outside the semiconductor storage device 10, and writes the received data to the selected memory cells. The sense circuit 3 contains multiple sense modules (sense amplifier modules) 3a. The sense modules 3a are connected to bit lines, respectively, and amplify the potentials on the corresponding bit lines. The semiconductor storage device 10 has a constitution that can hold 2 bits or more data in 1 memory cell. The column decoder 4 receives the column address signal from the address command register 7, and decodes the received column address signal. On the basis of the decoded address signal, the column decoder 4 controls input/output of data of the sense circuit 3.

The controller 5 receives the commands instructing read, write, delete, etc. from the address command register 7. On the basis of the instruction of the command, the controller 5 controls the voltage generator 8 and core driver 9 according to a prescribed sequence. According to the instruction of the controller 5, the voltage generator 8 generates all of the voltages, which will be explained later in the present specification, needed for the core operation. According to the instruction of the controller 5, the core driver 9 controls the row decoder 2 and the sense circuit 3 for controlling the word lines WL and bit lines BL. The input/output circuit 6 controls input from outside the semiconductor storage device 10 and output from the semiconductor storage device 10 to the outside of the commands, addresses, and data. The controller 5 controls the core driver 9, the row decoder 2, the sense circuit 3, and the column decoder 4 to carry out the following listed operations and the operations (write, etc.) in the various embodiments.

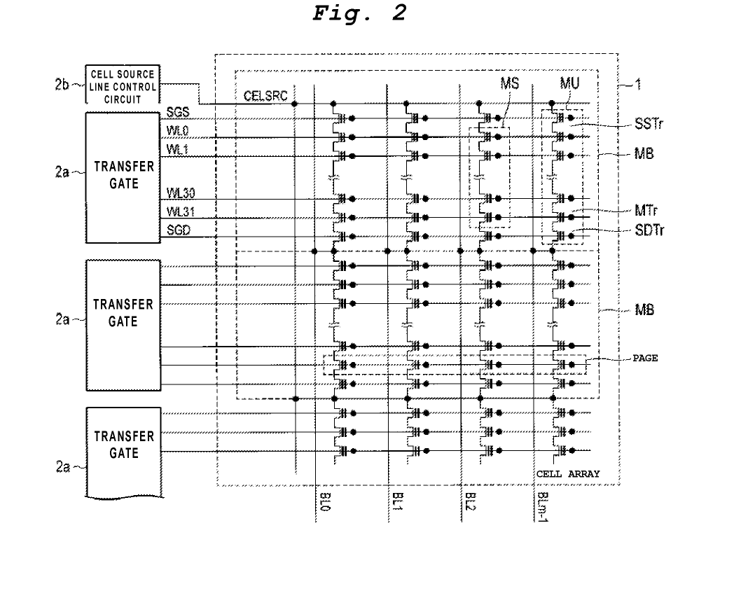

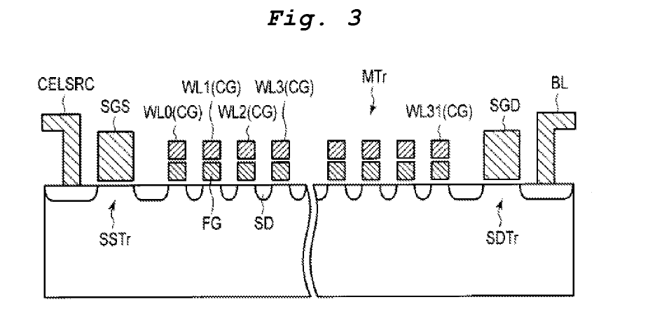

The memory cell array 1 has the structure shown in FIGS. 2 and 3. FIG. 2 is a circuit diagram illustrating the memory cell array of the semiconductor storage device related to Embodiment 1. FIG. 3 is a cross-sectional view illustrating the memory cell array of the semiconductor storage device related to Embodiment 1. As shown in FIGS. 2 and 3, the memory cell array 1 contains multiple blocks MB. Each block MB contains multiple memory units MU arranged side-by-side along the word line WL. Each memory unit MU contains selecting gate transistor SDTr, memory string MS, and selecting gate transistor SSTr. The memory string MS includes n (e.g., 32) memory cell transistors (cell transistors) MTr having the current routes (sources/drains) connected in series mutually. The transistor SDTr and transistor SSTr are connected to the two ends of the memory unit MU, respectively. The other end of the current route of the transistor SDTr is connected to the bit line BL, and the other end of the current route of the transistor SSTr is connected to the cell source line (source line) CELSRC.

The word lines WL0 to WL31 are connected to the multiple cell transistors MTr belonging to the same row in one block MB. The select gate line SGD is connected to all of the transistors SDTr in one block MB. The select gate line SGS is connected to all of the transistors SSTr in one block MB.

The collection of multiple cell transistors MTr connected to the same word line WL forms a page. When the semiconductor storage device 10 has a constitution that allows holding of multiple bits of data in each memory cell, multiple pages are allotted to one word line WL.

The cell transistors MTr are on the wells in a semiconductor substrate. Each of the cell transistors MTr has a tunnel insulating film (not shown in the figure) laminated on the well, a charge storage layer FG (such as floating gate electrode, insulating film having a trap, or their laminated film), an intermediate insulating film (not shown in the figure), a control electrode (control gate electrode) CG (word line WL), and a source/drain region SD. The source/drain regions of the adjacent cell transistors MTr are connected with each other. The selecting gate transistor SSTr and the selecting gate transistor SDTr contain a gate insulating film (not shown in the figure) laminated on a semiconductor substrate, gate electrodes (select gate lines) SGS, SGD, and source/drain region SD. The cell transistors MTr stores the nonvolatile data determined on the basis of the number of the electrons in the charge storage layer FG.

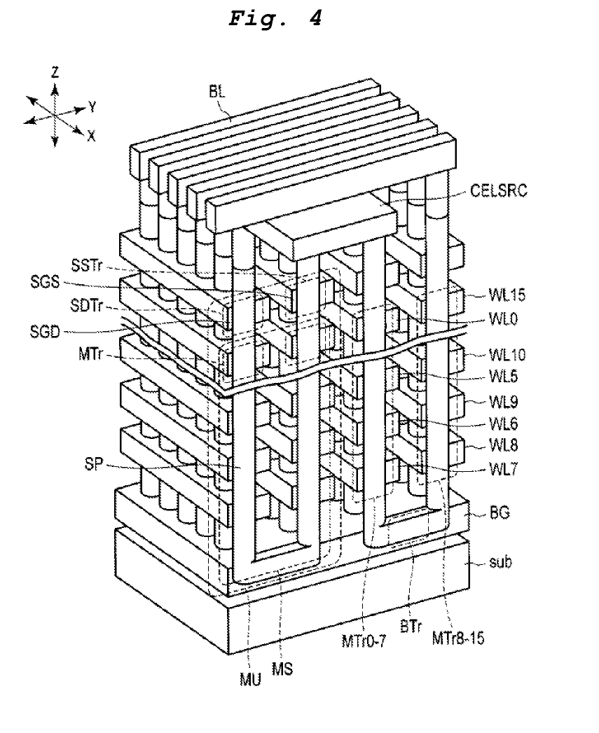

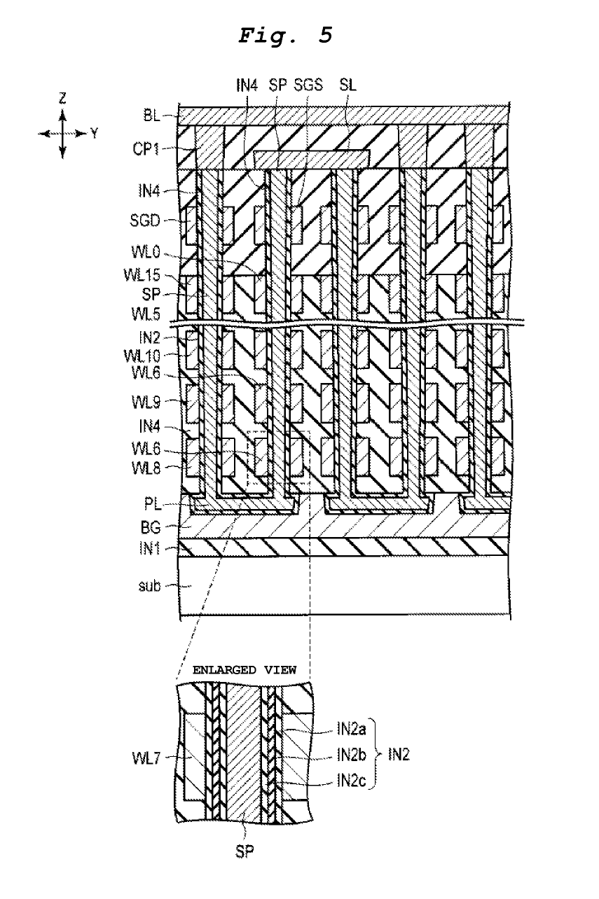

The memory cell array 1 may also have the three-dimensional structure shown in FIGS. 4 and 5. The semiconductor storage device 10 having the structure shown in FIGS. 4 and 5 is called BiCS memory. On the other hand, the semiconductor storage device 10 having the memory cell array shown in FIGS. 2 and 3 is called a planar memory (planar NAND). FIG. 4 is an oblique view illustrating another example of the memory cell array 1 of the semiconductor storage device related to Embodiment 1. FIG. 5 is a cross-sectional view taken across yz plane illustrating another example of the memory cell array 1 of the semiconductor storage device related to Embodiment 1. In FIGS. 4 and 5, the elements shown in certain drawings may be omitted for clarifying the drawings. As shown in FIGS. 4 and 5, a back gate BG made of an electroconductive material is formed via an insulating film IN1 above the substrate sub. The back gate BG is arranged spread along the xy plane. Also, multiple memory units MU are formed on the substrate sub.

FIGS. 4 and 5 illustrate an example in which the memory string MS contains 16 cell transistors (that is, n=16). The cell transistors MTr7 and MTr8 are connected to each other via the back gate transistor BTr. The transistors SSTr, SDTr are connected to cell transistors MTr0 and MTr15, respectively. Above the transistors SSTr, SDTr, the source lines CELSRC and bit line BL extend, respectively. The transistors SSTr, SDTr are connected to the source line CELSRC and bit line BL, respectively.

The cell transistors MTr0 to MTr15 contain the semiconductor pole SP and the insulating film IN2 on the surface of semiconductor pole SP, and they contain word lines (control gates) WL0 to WL15 extending along X-axis, respectively. The semiconductor pole SP is made of silicon in the interlayer insulating film IN3 on the back gate BG. The two semiconductor poles SP that form one memory string MS are connected by a pipe layer PL made of an electroconductive material in the back gate BG, and the pipe layer PL forms the back gate transistor BTr. The various word lines WL are shared by multiple cell transistors MTr arranged side-by-side along the X-axis. The collection of the multiple cell transistors MTr connected to the same word line WL forms a page. The insulating film IN2 spreads on the surface of the hole with the semiconductor pole SP formed in it, and, as shown in an enlarged figure, it contains a tunnel insulating film IN2a, a charge storage layer IN2b made of an insulating material, and an inter-electrode insulating film IN2c. The cell transistors MTr store the nonvolatile data determined on the basis of the number of the carriers in the charge storage layer IN2b.

The selecting gate transistors SSTr, SDTr contain a semiconductor pole SP, a gate insulating film IN4 on the surface of the semiconductor pole SP, and gate electrodes (select gate lines) SGS, SGD, respectively. The various gate electrodes SGS are shared by the multiple transistors SSTr arranged side-by-side along X-axis. The various gate electrodes SGD are shared by the multiple transistors SDTr arranged along X-axis.

The source line CELSRC is connected with multiple transistors SSTr. Each bit line BL is connected to multiple selecting gate transistors SDTr via plug CP1. The two adjacent memory units MU share the source line CELSRC.

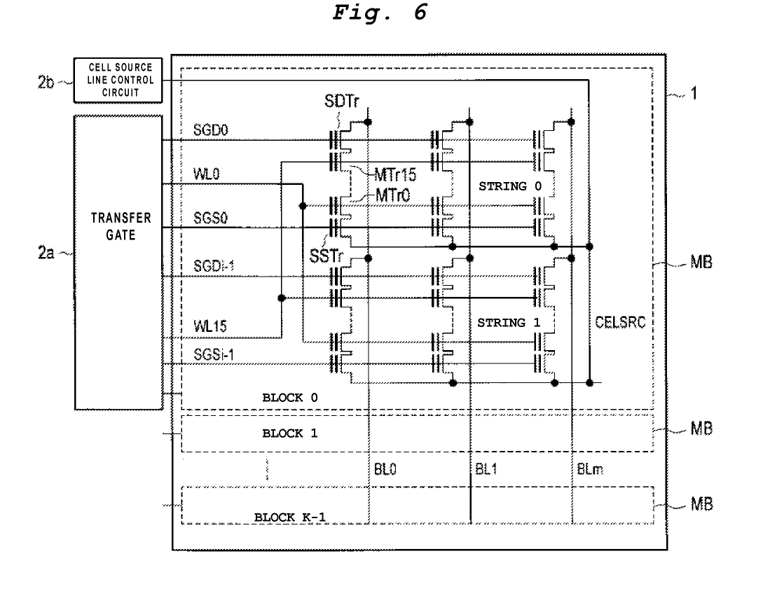

FIG. 6 is a circuit diagram illustrating the memory cell array of the semiconductor storage device related to Embodiment 1. It corresponds to the circuit diagrams shown in FIGS. 4 and 5. As shown in FIG. 6, the memory cell array 1 contains k−1 blocks MB. The bit lines BL0 to BLm−1 are arranged through all of the blocks MB. The bit line BL is connected to the corresponding one sense module 3a. The multiple cell transistors MTr0 arranged side-by-side in the left/right direction (X-direction shown in FIG. 4) are connected to the same word line WL0. The same is true for the word lines WL1 to WL15. The multiple transistors SDTr arranged side-by-side in the left/right direction are also connected to the same select gate line SGD. The multiple transistors SSTr arranged side-by-side in the left/right direction are also connected to the same select gate line SSDL. The multiple memory units MU (memory string MS and selecting gate transistors SSTr, SDTr) arranged side-by-side in the left/right direction and sharing the word line WL, select gate lines SGD, SGS form one unit. For example, this unit is called a string. In each block MB, i (i is, e.g., 2) string 0 to string i−1 are arranged.

In the block MB, the string 0 to string i−1 also share the word line WL. That is, in each block MB, the string 0 to string i−1 have their word lines WL0 connected with each other. The same is true for word lines WL1 to WL15. Connection of the memory unit MU of only one string to one bit line BL is carried out by electrically connecting the prescribed string to the bit line BL by control of transistors SDTr, SSTr.

The selection of the prescribed string, the prescribed block MB and the prescribed word line WL is carried out by the transfer gate 2a shown in FIG. 1. As explained above, in the BiCS memory, the multiple strings that share the bit line BL also share the word line WL. Consequently, when one word line WL is selected, and, the transistor SDTr (and/or SSTr) for prescribed one or multiple strings among the multiple strings sharing the word line WL is selected, the one or multiple strings are selected. On the other hand, even for a planar memory, as the SDTr (and/or SSTr) of the multiple memory strings MS that share the bit line BL is selected, and, at the same time, one word line WL of each memory string MS is selected, the multiple memory strings MS sharing the bit line BL are selected. Consequently, in the following explanation, the BiCS memory is also taken as corresponding to a planar memory. For example, the description of control of certain word line WL0 of the multiple strings in the BiCS memory to a prescribed potential is taken as also containing the description of control of the word line WL0 of the multiple strings of the planar memory to the same prescribed potential.

The constitution features shown in FIGS. 1 to 6 are also shared in all of the embodiments, that is, Embodiment 2 and thereafter to be explained later. In the following, only the features different from Embodiment 1 will be explained for Embodiment 2 and thereafter.

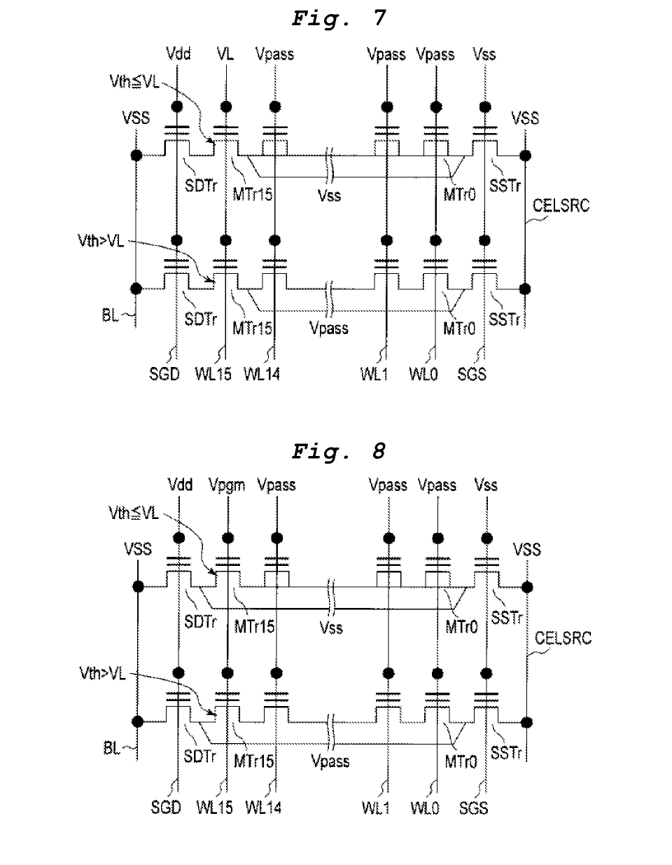

FIGS. 7 and 8 illustrate a state during write in the semiconductor storage device related to Embodiment 1. FIG. 8 is a diagram succeeding FIG. 7 in illustrating the state. FIG. 9 is a time chart illustrating the voltage during write in the semiconductor storage device related to Embodiment 1. In the following, explanation will be made on BiCS memory as an example. FIG. 9 corresponds to time charts in FIGS. 7 and 8. Explanation will be made schematically on the write of Embodiment 1 wherein whether write is made in the cell transistor MTr or not is determined automatically corresponding to the threshold voltage of the cell transistor MTr (select cell transistor) as the write object. There is no need to make selection via the voltage of the bit line BL. More specifically, the channel makes transition to a prescribed state only for the cell transistors having a threshold voltage lower than the target among the cell transistors MTr sharing the word line (selected word line) WL selected from the multiple memory strings MS. The combination of the cell transistor MTr in the prescribed state and application of the program voltage Vpgm to the selected word line WL leads to formation of the state (program state) wherein write is carried out to the cell transistor MTr. On the other hand, for the cell transistor MTr not in the prescribed state, even when the program voltage Vpgm is applied, write is still not executed in this state formed here (inhibit state).

In the following, more detailed explanation will be made with reference to FIGS. 7 to 9. Here, for the row decoder 2, sense circuit 3, column decoder 4, controller 5, voltage generator 8, and core driver 9, operation is carried out as the voltage is applied with the timing to be explained below. In the following description, as an example, the cell transistor MTr15 nearest the transistor SDTr is taken as the write object. Write to the cell transistor MTr0 nearest the transistor SSTr will be explained later. Also, write to the cell transistor MTr other than the two ends of the memory string MS will be explained in Embodiment 5. The verify voltage VL is the voltage applied on the cell transistor MTr for checking end of write when the conventional write instead of the write related to the present embodiment is carried out. In other words, the verify voltage VL is equal to the desired target threshold voltage after write in the cell transistor MTr. In order to carry out write, the voltage is repeatedly applied on the cell transistor MTr, and, it is determined that the cell transistor MTr having a threshold over the verify voltage VL is success (completion) of write. The verify voltage VL has a value corresponding to the written data. For example, when the cell transistors MTr store the 2-bit 4-value data, there exist multiple verify voltages VL corresponding to the various data.

As shown in FIGS. 7 and 9, first of all, at time t1, the select gate line SGD of the selected memory string MS is driven from voltage Vss (low level) to Vdd (high level). During the write, that is, during the period shown in FIG. 9, voltage Vss is maintained for the select gate line SGS, the bit line BL, and the source line CELSRC. During the write period, the voltage Vss is maintained at the select gate lines SGD, SGS (USGD, USGS) of the non-selected block MB.

At time t2, the non-selected word lines WL (WL0 to WL14) are driven from voltage Vss to voltage VPASS. Here, the voltage Vpass is the intermediate voltage between the voltage Vss and the voltage Vpgm, and it is the voltage applied on the non-selected word lines WL in the conventional write system. At time t3, the selected word line WL (WL15) is driven from voltage Vss to voltage VL. As a result, on the basis of threshold voltage Vth of the cell transistor MTr15 connected with the selected word line WL, any of the following states is taken for the selected memory string MS. As shown in FIGS. 7 and 8, the upper portion shows the case when Vth≦VL for cell transistor MTr15, that is, when write in the cell transistor MTr15 is not ended. On the other hand, the lower portion shows the case when Vth>VL for the cell transistor MTr15, that is, when write in the cell transistor MTr15 is ended. In the following, the cases will be explained respectively.

### 1. When Vth≦VL

The cell transistor MTr15 is turned on. As a result, the channels of all of the cell transistors MTr0 to MTr14 remaining in the memory string MS are electrically connected to the bit line BL via the cell transistor MTr15, and voltage Vss is reached.

### 2. When Vth>VL

The cell transistor MTr15 is kept off, and the channels of all of the remaining cell transistors MTr0 to MTr14 in the memory string MS become floating. As a result, coupling takes place between the channel and the voltage Vpass applied on the non-selected word lines WL, that is, the so-called channel boosting takes place. Due to channel boosting, the channel voltage of the cell transistor MTr rises to about the Vpass. The degree of the channel voltage depends on the coupling ratio between the channel and the word line WL. In this way, only when there is a state of Vth>VL for the selected cell transistor MTr15, the channel boosting takes place in the memory string MS. That is, there are memory strings MS where the channel boosting took place and the memory strings MS where the channel boosting did not take place.

Then, as shown in FIGS. 8 and 9, at time t4, the select gate line SGD is reset to the voltage Vss, and the transistor SDTr is turned off. As a result, even when the cell transistor MTr15 is in the state of Vth≦VL, the channel in the memory string MS becomes floating. When the cell transistor MTr15 becomes the state of Vth>VL, there is no change in the state.

At time t5, the program (write) voltage Vpgm is applied to the selected word line WL. As this voltage is applied, the voltage of the channels of the cell transistors MTr0 to 14 is also transferred to the channel of the cell transistor MTr15, and the state of the channel in the memory string MS becomes one of the following listed states on the basis of the threshold voltage of the cell transistor MTr15.

### 1. When Vth≦VL

In the selected cell transistor MTr15, the word line WL has the program voltage Vpgm, and the channel has the voltage Vss. That is, the program state takes place, and write is carried out in the cell transistor MTr. For the non-selected cell transistors MTr, as the word line potential is Vpass, write is not carried out.

### 2. When Vth>VL

In the selected cell transistor MTr15, the word line WL has the program voltage Vpgm, while the channel has the voltage Vpass. Consequently, the program state does not take place, that is, the inhibit state takes place, and write is not carried out to the cell transistor MTr15. In the non-selected cell transistors, as the word line potential is Vpass, write is not carried out.

Only when the selected cell transistor MTr15 is in the state of Vth≦VL, the program state is formed. In addition, as the selected word line WL is raised to the program voltage Vpgm, further channel boosting can take place. However, if there are a sufficiently large number of non-selected cell transistors MTr, they can overwhelm the additive channel boosting, and the channel can be kept in the state before application of the program voltage. That is, the capacitance ratio of the selected cell transistor MTr to the selected word line WL should be lower than the sum of the capacitance ratio of all of the non-selected cell transistors MTr to the non-selected word lines WL in the same memory string MS. Consequently, there should be at least two non-selected cell transistors MTr.

Then, at time t6, all of the word lines WL are reset to voltage Vss, and the semiconductor storage device 10 makes transition to the standby state. In FIGS. 7 and 8, only one bit line BL and the elements connected to it are shown. However, write may also be carried out in parallel for the other bit lines BL in one string and the elements connected to them. That is, it is also possible to carry out write to 1 page.

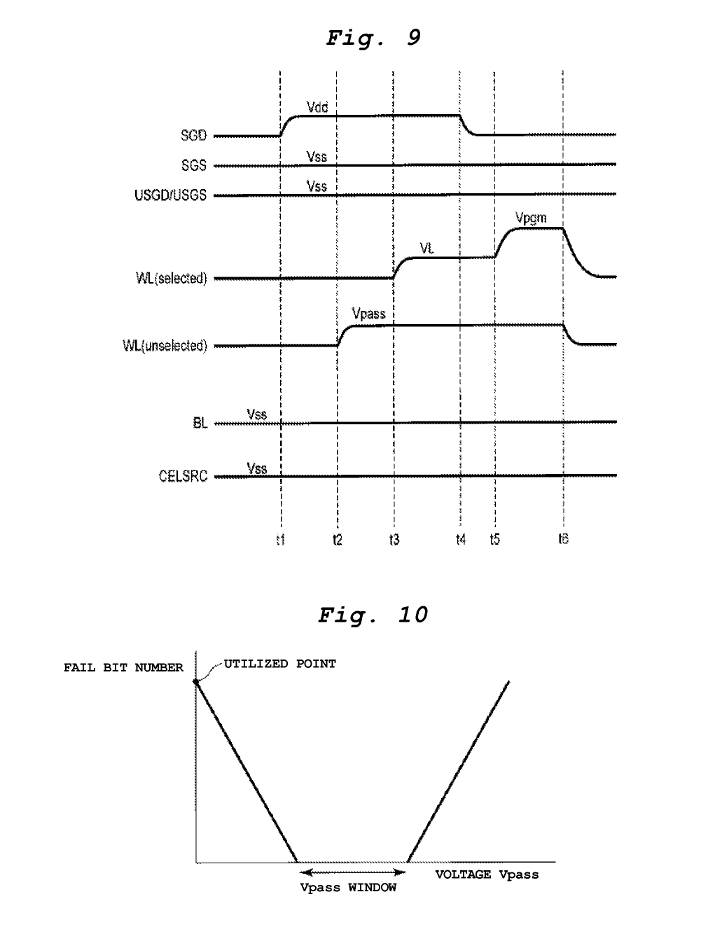

FIG. 10 is a diagram illustrating one side surface of the principle of write related to Embodiment 1. More specifically, FIG. 10 is a diagram illustrating the relationship between the voltage Vpass and the fail bit number in the write method in the related art. As shown in FIG. 10, for the voltage Vpass, there is a range required for appropriate write (Vpass window). If this range is overrun, the smaller the voltage Vpass, the larger then fail bit number. The channel of the cell transistor that receives the program voltage Vpgm among the non-selected string is the voltage Vpass due to transfer of the voltage from the channel of the remaining cell transistors in the same string, and the program state is formed by excessively low voltage Vpass. Also, when the appropriate range is overrun, the larger the voltage Vpass, the larger the fail bit number. The excessively high voltage Vpass becomes near the program voltage Vpgm, so that the program state takes place in the non-selected cell transistors in the selected string. On the other hand, according to Embodiment 1, write is carried out by exploiting the state wherein the voltage Vpass is the lowest (that is, Vpass=Vss), that is, the state wherein the fail bit number is the largest according to the conventional idea. In this way, the write operation in Embodiment 1 exploits the state that is the most problematic in the prior art, and it is different from the conventional write operation.

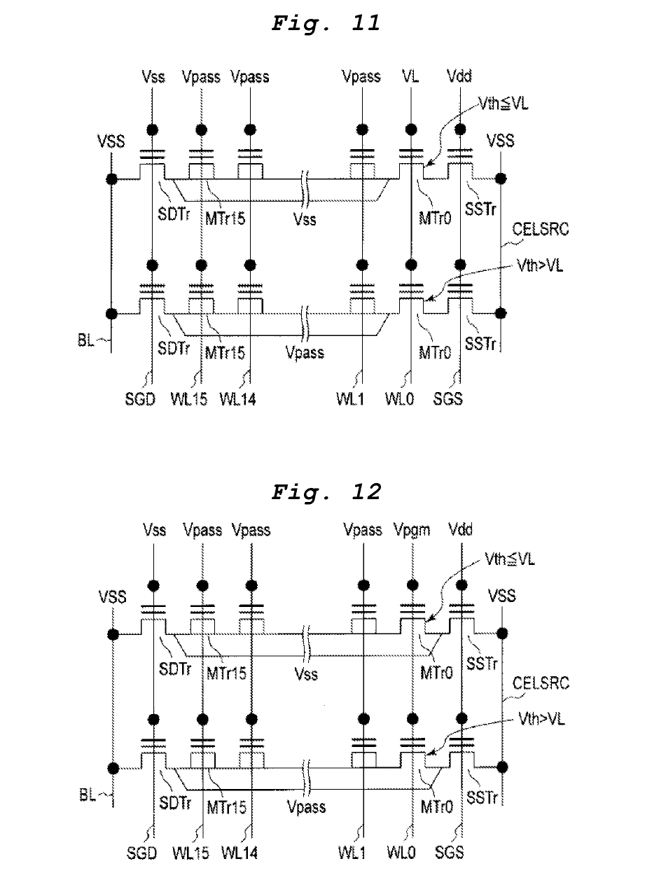

FIGS. 7 and 8 relate to an example wherein the cell transistor MTr15 nearest the transistor SDTr in the string is the write object. Even in the case wherein the selected cell transistor MTr is nearest the transistor SSTr, it is possible to write with the same principle. Different from the technology whereby the potential on the bit line BL is used to form the program state and inhibit state respectively, in this case, the bit line BL is kept at the voltage Vss during write just as the source line CELSRC. FIG. 11 is a diagram illustrating another state during write in Embodiment 1. FIG. 12 is a diagram succeeding FIG. 11 for illustrating the state. FIGS. 11 and 12 show the voltages applied on the various parts left/right inverted with respect to those shown in FIGS. 7 and 8. That is, the select gate line SGS has voltage Vdd, and the select gate line SGD is kept at Vss. Then, the select gate line SGS is reset to the voltage Vss, and the cell transistor MTr0 is driven to the program voltage Vpgm. The roles of the bit line BL and the source line CELSRC can be swapped, and the roles of transistor SDTr and transistor SSTr can be swapped.

As explained above, for the semiconductor storage device related to Embodiment 1, on the basis of the threshold voltage of the selected cell transistor MTr, the selected cell transistor MTr is automatically set in the program state or the inhibit state. Selection of the two states is irrelevant to the voltage on the bit line BL. Consequently, there is no need to carry out charging/discharge for the bit line BL for selecting the two states. The power consumption needed for write is smaller than that when the two states are selected using the bit line BL, and the write is also quicker. In addition, as there is no potential difference between the source line CELSRC and the bit line BL during write, it is also possible to suppress the leak current in the non-selected blocks.

### Embodiment 2

Embodiment 2 relates to the sequence of write when Embodiment 1 is adopted.

In the prior art, for the verify write for each bit, repeated setting of verify by write and read is carried out. As a result of read, for the verified cell transistor, during the period of application of the later write voltage, the inhibit state is maintained by control of the potential of the bit line BL. On the other hand, as mentioned previously, write in Embodiment 1 makes automatic transition to the program state or the inhibit state for the selected cell transistor on the basis of the threshold voltage of the selected cell transistor MTr. In Embodiment 2, this characteristic feature is exploited, so that it is possible to realize write the same as the write including verify without carrying out read. The more specific scheme is as follows. Usually, in the NAND-type flash memory (including the BiCS memory), the upper limit of the number of rounds of application of the write voltage (the upper limit of the loop round number) is determined. Even when this upper limit is reached, if the target threshold voltage is not reached, the write is taken as a fail. In order to determine the upper limit, for the NAND-type flash memory, the characteristics are checked, and the upper limit loop round number is calculated. In Embodiment 2, it is guaranteed that write is ended even without carrying out read for verify when write of Embodiment 1 is repeated for the upper limit loop round number.

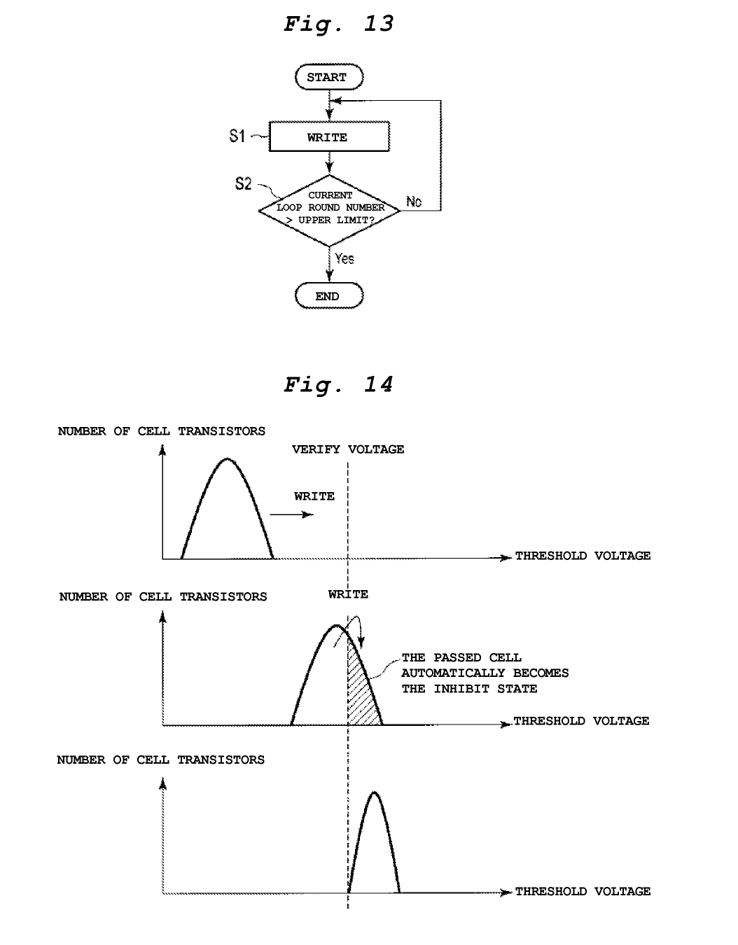

FIG. 13 is a flow chart illustrating the write operation related to Embodiment 2. As shown in FIG. 13, write is carried out (step S1). The write operation in step S1 is carried out using the write in Embodiment 1. Also, write in step S1 includes one round of write in Embodiment 1, and it does not include read for verify. By means of the write, write is carried out as the verify voltage VL is taken as the target threshold voltage for the selected cell transistor MTr. By the write in Embodiment 1, among the multiple selected cell transistors MTr, the program state takes place for the incomplete selected cell transistors, and the inhibit state takes place for those that has write ended.

Then, for example, the controller 5 determines whether the application round number (loop round number) of the current write voltage is over the upper limit (step S2). As explained above, this upper limit is pre-determined on the basis of the characteristics of the semiconductor storage device 10. That is, the maximum loop round number needed for end of write among the multiple (e.g., all of) the cell transistors MTr is determined, and the maximum loop round number is adopted as the threshold in step S2. Also, it is not necessary to determine the maximum loop round number for all of the cell transistors MTr as the object. That is, for example, the maximum loop round number is used among the cell transistors MTr with ended write at the time within the write time range determined for semiconductor storage device 10. The cell transistors MTr with the write time above the requested write time are taken as defective bits, and error detection and then error correction are carried out using, safely, ECC (error correction code). If determination in step S2 is NO, the flow returns to step S1. Here, as the loop number is increased, the program voltage Vpgm also increases by a prescribed amplitude. If the determination in step S2 is YES, the flow ends. By determining of YES in step S2, write should have been ended for all of the selected cell transistors (such as the cell transistors with risen threshold voltage in 1 string) MTr. Consequently, there is no need to carry out read for verify after each write in step S1.

FIG. 14 is a diagram illustrating the transition of the cell transistor threshold voltage distribution due to write related to Embodiment 2. As shown in the upper portion of FIG. 14, before write, certain selected cell transistor is the verify voltage VL or lower, and the right hand end of the threshold voltage distribution is the verify voltage VL or lower. Each time of write, the threshold voltage of all of the cell transistors MTr rises, so that the distribution curve shifts to the right hand side. As shown in the middle section of FIG. 14, as a result of certain rounds of write, the threshold voltage of the cell transistor MTr having a high threshold voltage is over the verify voltage VL. That is, after that, for the cell transistor MTr (indicated by hatched portion) over the threshold voltage, the inhibit state is automatically taken for write, and the threshold voltage does not rise. On the other hand, for the cell transistor MTr not over the threshold voltage, the program state is automatically taken, and the threshold voltage rises. As the step of operation is repeated, as shown in the lower portion of FIG. 14, all of the cell transistors MTr become over the verify voltage VL, that is, the left hand end of the distribution curve is over the verify voltage VL.

The distinguishing of the program state and the inhibit state by the voltage of the bit line BL is usually a discrete control to have the bit line voltage to be either Vdd or Vss. On the other hand, write related to Embodiment 2 allows continuous or at least fine stepwise control to be explained below. That is, the cell transistor MTr makes stepwise transition from the program state to the inhibit state. As the threshold voltage of the cell transistor MTr approaches the verify voltage VL, the channel voltage of the voltage Vss that has the highest program state gradually makes transition to the voltage Vpass corresponding to the inhibit state. In other words, the highest program state makes transition to the weak program state, and this transition can avoid excessive application of the program voltage to the cell transistor. Such control usually can be realized by QPW (quick pass write). The QPW is a scheme whereby an intermediate voltage between the voltage Vdd and the voltage Vss is adopted as the bit line voltage in the technology for distinguishing the program state and the inhibit state by the bit line voltage. However, according to Embodiment 2, it is possible to make transition of state in finer steps as those of QPW, and it is also possible to perform the automatic transition of state.

As explained above, according to Embodiment 2, the write operation of Embodiment 1 is carried out repeatedly in a round number that guarantees write independent of the dispersion in the characteristics of the cell transistor MTr. By using the write of Embodiment 1, the same advantages as those of Embodiment 1 are realized, and, at the same time, write can be guaranteed without carrying out read for verify each time of write. For the NAND-type flash memory including the BiCS memory, the set of program voltage application and read is repeated. Different from this scheme, according to Embodiment 2, read in each set is omitted, and it is possible to suppress the write time. In addition, according to Embodiment 2, it is possible to realize the automatic stepwise transition from the program state to the inhibit state.

### Embodiment 3

Embodiment 3 relates to the parallel write to multiple strings by exploiting Embodiment 1.

In the write carried out using the bit line voltage in the prior art, it is required that during the period of read and write, only one memory string MS is connected to one bit line. In order to execute such operation, in the case of the BiCS memory, by on/off of the transistor SDTr, among the multiple strings connected to the same bit line BL, only the memory string MS in the selected string is connected to the bit line. This restriction is also applied on read for verify in the prior art. Consequently, in the write operation in the prior art, although it is possible to select multiple pages by selecting one word line over multiple strings, it is nevertheless possible to take only one string as the object for each bit line. Here, measures may be adopted to address the problem. For example, according to one measure, instead of the verify for each string, write is also carried out to the cell transistors for which write is already ended before end of write in all of the selected cell transistors that share the bit line and word line. As another measure, write is ended at the time point when write to one cell transistor is ended. On the other hand, for write in Embodiment 1, there is no need to make change in voltage of the bit line BL in read for verify. Consequently, Embodiment 1 is exploited to carry out write to multiple strings simultaneously while the same effect as that of verify is realized using the write in Embodiment 1.

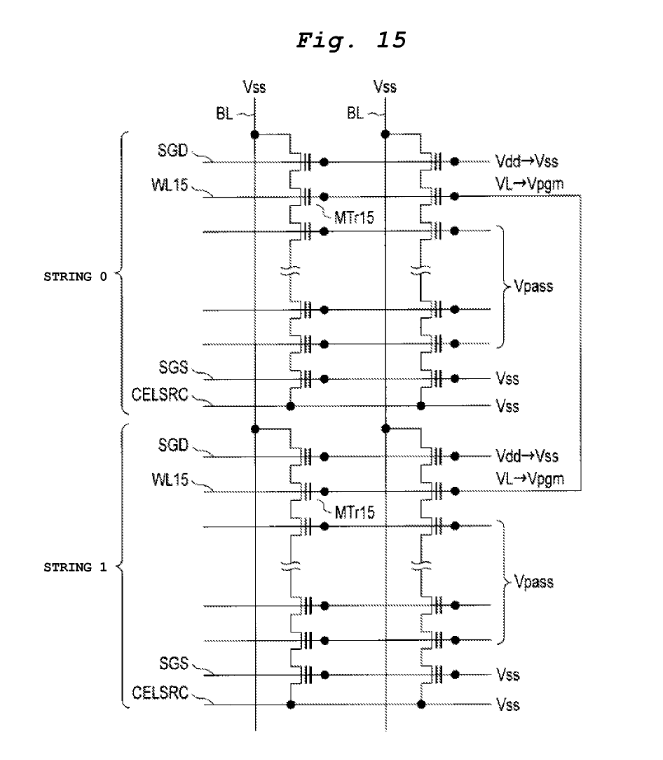

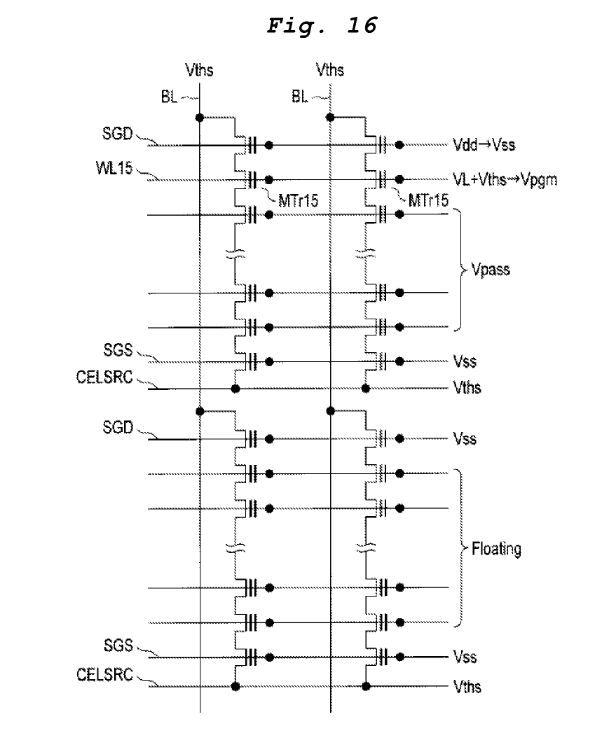

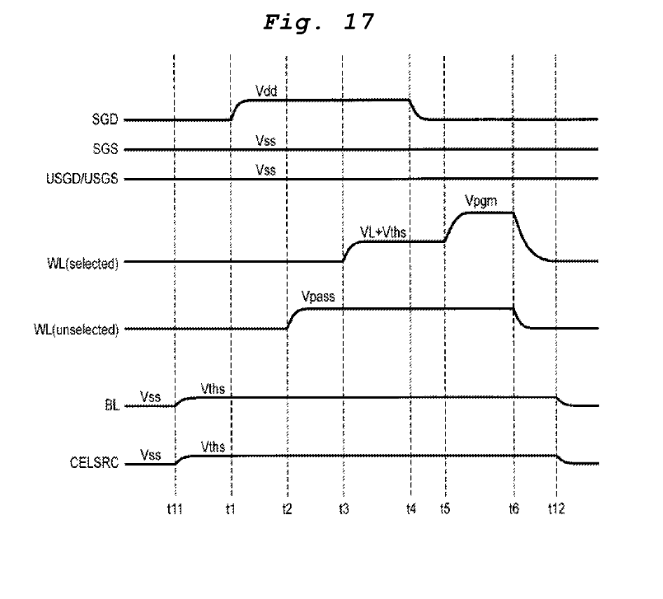

FIG. 15 is a diagram illustrating a state during write in Embodiment 3. In FIG. 15, only strings 0 and 1 are shown as the selected strings. However, the following explanation also applies on the other strings. FIG. 15 shows the write to the cell transistor MTr15 nearest the transistor SDTr similarly to Embodiment 1. As described in Embodiment 1, the cell transistor MTr0 nearest the transistor SSTr may also be taken as the object.

First of all, just as in FIG. 7, for each of all of the selected strings, the select gate line SGD is set at voltage Vdd, and the select gate line SGS and source line CELSRC are kept at voltage Vss. The bit lines BL are all kept at voltage Vss. In addition, the selected word line WL15 is driven to the verify voltage VL. As all of the strings in 1 block share the various word lines, in all of the strings, the selected word lines WL15 rise to the verify voltage. All of the non-selected word lines are kept at voltage Vpass.

Then, just as in FIG. 8, the select gate line SGD in each selected string is reset to voltage Vss. After that, each selected word line WL15 is driven to voltage Vpgm. In this step of operation, among the cell transistors MTr 15 in the various selected strings, the program state takes place for those having a threshold voltage of the verify voltage VL or lower, and the inhibit state takes place for those having a threshold voltage over the verify voltage. In this way, write is carried out in parallel for the multiple strings that share the word lines WL. In addition, Embodiment 2 may be adopted in Embodiment 3. As a result, after end of write, the multiple selected cell transistors MTr in the various selected strings automatically become the inhibit state even with respect to application of the write voltage. In this way, the multiple selected cell transistors MTr are taken as the object for write until end of the write operation.

As can be seen from the explanation, for the multiple cell transistors MTr connected to the selected word line WL, write is carried out with the same verify voltage VL as the target threshold voltage. Consequently, in Embodiment 3, the scheme can be adopted in the EP write of the BiCS memory. Here, the EP write refers to the operation wherein in order to improve the data resistivity, the threshold voltage of the cell transistor is set in the so-called E state (the negative threshold voltage state) by deletion, and then the threshold voltage is changed to a positive value to have the EP state. For the BiCS memory, the EP state corresponds to the deletion state. As the EP write is an operation wherein the same threshold voltage is applied for the multiple cell transistors MTr, it is well suited to Embodiment 3.

As explained above, according to Embodiment 3, write in Embodiment 1 is carried out in parallel for multiple strings sharing the word lines WL. By utilizing the write in Embodiment 1, the same merits of those in Embodiment 1 can be realized, and, at the same time, as write is carried out in parallel for the multiple strings, it is possible to efficiently exploit the effect of sharing of the word lines WL by multiple strings, one of the characteristic features of the BiCS memory.

### Embodiment 4

Embodiment 4 relates to a side surface of Embodiment 1. More specifically, it relates to an example wherein the transistors SDTr, SSTr have a negative threshold voltage.

In the write operation using the bit line voltage in the prior art, the program state and inhibit state are formed respectively depending on the relationship between the bit line voltage and the threshold voltage of the drain-side select gate transistor (SDTr). Consequently, the condition determined by the distribution of the threshold voltage of all of the drain-side select gate transistors is restricted by the voltage Vss, Vdd applied on the bit lines. That is, suppose the lower end of the threshold distribution of the drain-side select gate transistor is Vths (min), and its upper end is Vths (max), it is necessary to meet the relationship of Vdd>Vths (max) and Vths (min)>Vss. Consequently, the conventional write operation cannot be carried out when the threshold distribution of the drain-side select gate transistor is extremely wide, or when at least a portion of the distribution is in the negative region, etc. When the threshold voltage of certain drain-side select gate transistor is negative, one may adopt a scheme in which the voltage at the drain and source shifts in the positive direction while the gate voltage of the transistor is held. However, in this case, a high voltage is needed as the high level, so that it is necessary to prepare a higher power supply voltage or to improve the sense amplifier to output a higher voltage. In the former case, the power consumption is increased. In the latter case, the circuit area becomes larger.

On the other hand, the write operation related to Embodiment 1 requires only one bit line voltage Vss. Consequently, the write operation related to Embodiment 1 can be adopted appropriately for the transistors SDTr having a negative threshold voltage or having a very wide distribution of the threshold voltage with less restriction than that in the prior art.

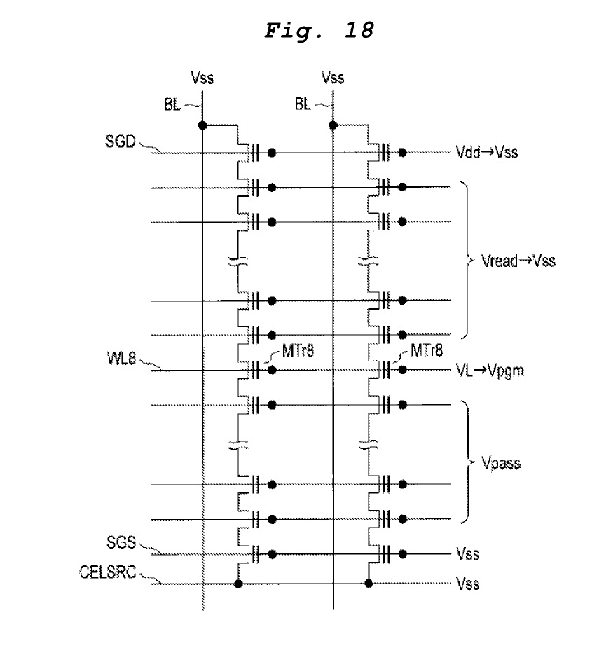

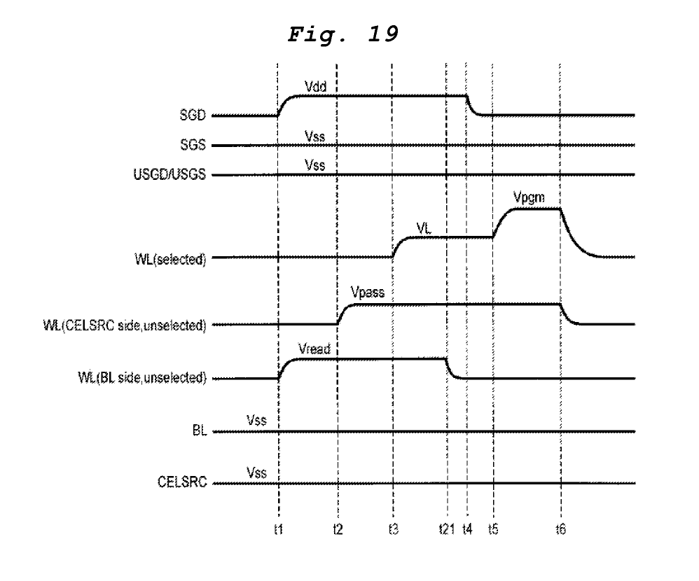

FIG. 16 is a diagram illustrating the state during the write operation related to Embodiment 4. FIG. 17 is a time chart illustrating the voltage during the write operation related to Embodiment 4 of the present disclosure. FIGS. 16 and 17 relate to an example wherein the threshold voltages of the transistors SDTr, SSTr are negative. Generally speaking, Embodiment 4 is very similar to Embodiment 1 (FIGS. 7 to 9). It differs from Embodiment 1 in that instead of voltage Vss in Embodiment 1, voltage Vths becomes the voltage applied on the bit line BL and the source line CELSRC, and, instead of the voltage VL in Embodiment 1, the voltage VL+Vths becomes the voltage applied on the selected word line WL. Here, the voltage Vths is the absolute value of the minimum negative threshold voltage among all of the transistors SDTr, SSTr in the semiconductor storage device 10. The voltage Vths is superposed on the bit line BL and the source line CELSRC to ensure that even when there is the negative minimum threshold voltage, the transistors SDTr, SSTr are still turned off by the select gate lines SGD, SGS of the voltage Vss.

First of all, at time point t11 proceeding the time point t1, the bit line BL and the source line CELSRC are driven from the voltage Vss to the voltage Vths. At time points t3 to t4, as shown in FIG. 9, instead of the voltage VL, the voltage VL+Vths is applied to the selected word line WL. After application of the voltage Vpgm, at time point t12 succeeding time point t6, the bit line BL and the source line CELSRC are reset to the voltage Vss.

As explained above, in Embodiment 4, the write operation in Embodiment 1 is adopted in the case when the transistors SDTr, SSTr have negative threshold. As the write operation of Embodiment 1 is adopted, the same merits as those in Embodiment 1 can be obtained, and, at the same time, compared with the conventional write operation, there is less restriction in the case when the transistors SDTr, SSTr have a negative threshold voltage or a very wide threshold distribution. Embodiment 4 may also be combined with Embodiment 2 and (or) Embodiment 3.

### Embodiment 5

Embodiment 5 relates to the write operation in the cell transistors other than the ends of the memory string exploiting Embodiment 1.

In order to carry out the write operation to the cell transistors not at the ends of the memory string, the non-selected cell transistors (the bit line-side non-selected cell transistors) MTr nearer the bit line side than the selected cell transistor MTr receives the same voltage as that for transistor SDTr in Embodiment 1. Also, in order to carry out write to the cell transistor MTr on the non-memory string end, it is preferred that all of the transistors nearer the bit line side than the selected cell transistor MTr, that is, all of the transistor SDTr and the bit line-side non-selected cell transistors MTr have a positive threshold voltage. The reason is as follows: in the standby state, the cell transistors MTr are cut off due to application of the voltage Vss to be explained later. In order to meet the requirement, write is carried out sequentially from the cell transistor MTr at the end of the memory string towards the cell transistor MTr at the center of the memory string MS. For the BiCS memory, in order to improve the data retentivity, EP write having the threshold voltage moving to the positive side may take place with respect to the cell transistor MTr having a negative threshold voltage after deletion. For example, the EP write operation is carried out on the cell transistor MTr adjacent to the cell transistor MTr that has finished write in certain string. Consequently, Embodiment 5 is appropriate for application in the BiCS memory.

FIG. 18 is a diagram illustrating the state during the write operation related to Embodiment 5. FIG. 19 is a time chart illustrating the voltage during write related to Embodiment 5. Preceding that shown in FIG. 18, in all of the cell transistors MTr nearer the side of the bit line BL than the selected cell transistor MTr8, sequential write from the string end comes to an end.

As shown in FIGS. 18 and 19, at time point t1, in addition to start of driving of the select gate line SGD to voltage Vdd, all of the non-selected word lines nearer the bit line side than the selected cell transistor MTr (the bit line-side non-selected word lines) are driven from voltage Vss to voltage Vread. Here, the voltage Vread is a voltage applied on the non-selected transistors MTr when read is carried out, and it has a level that turns on the non-selected transistors MTr. Asa result, all of the bit line-side non-selected transistors MTr are turned on. Then, at time point t2, all of the non-selected word lines WL (the source line-side non-selected word lines) nearer the source line side than the selected cell transistor MTr are driven by the voltage Vpass, and, at time t3, the selected word line WL is driven to voltage VL. Due to driving to the voltage VL, corresponding to the threshold voltage of the selected cell transistor MTr, the channels of all of the non-selected cell transistors (the source side non-selected transistors) MTr from the selected cell transistor MTr to the source line CELSRC are kept at Vss, or are boosted to the voltage Vpass. At time point t21 proceeding time point t4, the bit line-side non-selected word lines WL are reset to voltage Vss.

Then, just as in Embodiment 1, the select gate line SGD is reset to voltage Vss, and the selected word line WL is driven to voltage Vpgm, so that write is carried out to the cell transistor MTr having a threshold of voltage VL or lower.

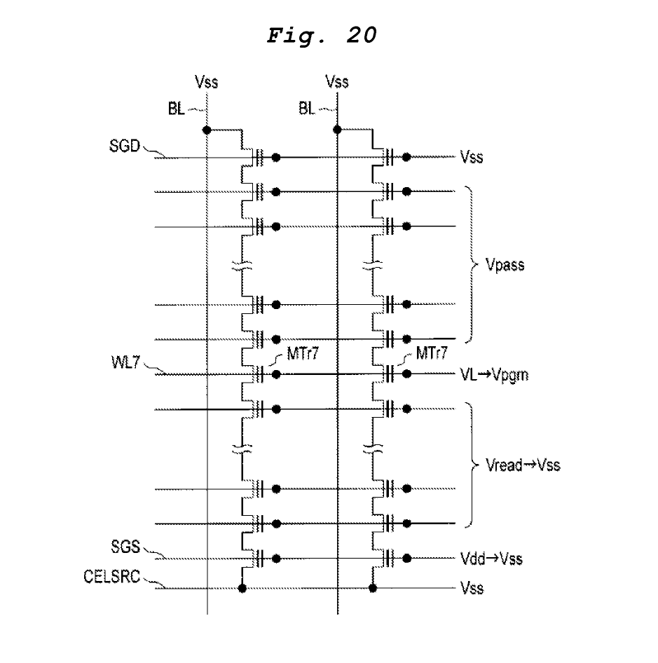

When write is carried out to the cell transistor MTr nearer the source line CELSRC, the number of the non-selected cell transistors MTr with the channel boosted to the voltage Vpass becomes smaller. Consequently, there is a possibility that the channel of the selected cell transistor MTr cannot be boosted to voltage Vpass, and a sufficient inhibit state cannot be formed. Here, as shown in FIG. 20, when write is carried out in the cell transistor MTr nearer the source line CELSRC, write is carried out sequentially from the cell transistor at the end of the cell string on the side of the source line CELSRC to the central cell transistor MTr of the string. FIG. 20 is a diagram illustrating a state during write related to the second example of Embodiment 5. As shown in FIG. 20, instead of the select gate line SGD, the select gate line SGS is driven to voltage Vdd, and the select gate line SGD is kept at voltage Vss. Instead of the bit line-side non-selected word lines WL, the source side non-selected word lines WL are driven from voltage Vss to voltage Vread. The bit line-side non-selected word lines WL are driven to Vpass.

In order to guarantee that the bit line-side non-selected transistors MTr have a positive threshold voltage, for example, the technology described in Japanese Patent Application No. 2011-20117 can be adopted in Embodiment 5. Japanese Patent Application No. 2011-20117 describes as follows: when write is instructed on the cell transistor WLN, before write is carried out in the cell transistor WLN, EP write is carried out in the adjacent cell transistor WLN+1 on the rising order side of the cell transistor WLN. By using this technology, when write is carried out in the order from the cell transistor MTr nearer the bit line BL, EP write is carried out in the cell transistor MTrN−1 before write to certain cell transistor MTrN. Then, even when write is carried out in the cell transistor MTrN−2 without write in the cell transistor MTrN−1, at the time point of write in the cell transistor MTrN−2, the cell transistor MTrN−1 has a positive threshold voltage. Consequently, it is possible to guarantee a positive threshold voltage for the bit line-side non-selected cell transistor MTr.

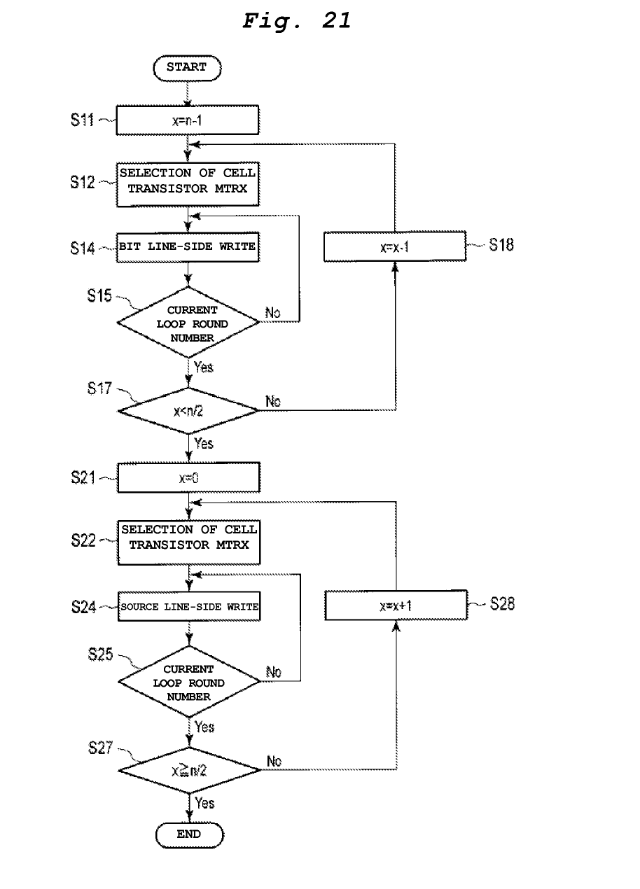

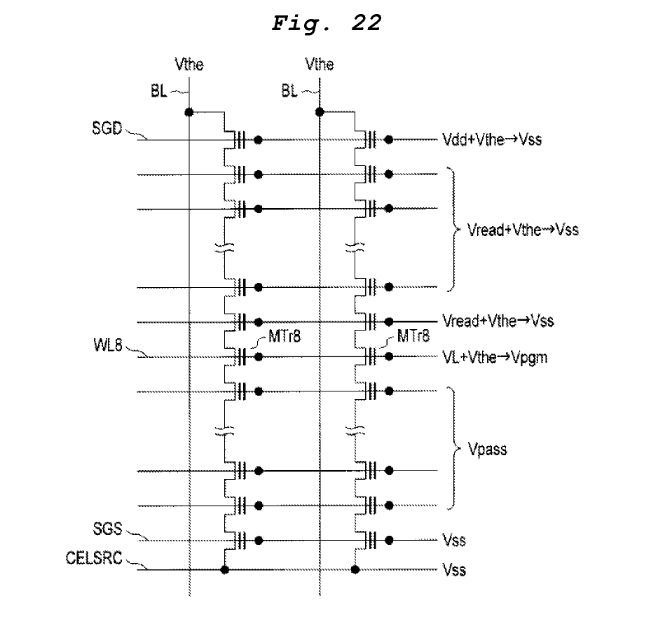

In the following, the write operation in the practical operation will be explained with respect to FIG. 21. FIG. 21 is a flow chart illustrating the write related to the third example of Embodiment 5, and it is a flow chart illustrating the write in one block MB. First of all, for example, the controller 5 sets the current value x kept in a register to n−1 (step S11). Here, one should pay attention to the fact that n represents the number of the cell transistors in the cell string as explained above. Then, the controller 5 selects the cell transistor MTrx defined by the current value x (step S12), and carries out the write as described with reference to FIG. 18 to the selected cell transistor MTr (step S14). The write shown in FIG. 18 is that when the cell transistor MTr is nearer the bit line BL, it will be referred to as the bit line-side write hereinafter.

Just as in Embodiment 2, the controller 5 counts the number of rounds of write in the cell transistor MTr. Then, the controller 5 determines whether the write in the selected cell transistor MTr becomes over the upper limit (step S15). Step S15 is the same as the step S2 shown in FIG. 13. The upper limit adopted in step S15 is the same as the upper limit explained in Embodiment 2. If the determination result in step S15 is NO, the flow returns to step S14. On the other hand, if the determination result in step S15 is YES, it goes to step S17. The controller 5 then determines in step S17 whether the current value x is smaller than x/2. If the determination result is YES in step S17, the controller 5 refreshes the current value x to x−1 (step S18). Then, the flow returns to step S12, and, for the refreshed current value x, the operation of steps S12, S14 and S15 is repeated. That is, the bit line-side write is carried out in the cell transistor MTr adjacent on the source line side to the last-round selected cell transistor MTr. Until the determination result becomes NO in step S17, write in all of the cell transistors MTr nearer the bit line BL is carried out repeatedly sequentially from the cell transistor MTr at the end on the bit line side towards the source line CELSRC.

In step S17, after end of write to all of the cell transistors MTr nearer the bit line BL, the flow goes to step S21. In step S21, the controller 5 sets the current value x to 0. Next, the controller 5 selects the cell transistor MTrx determined by the current value x (step S22), and write is carried out as described with reference to FIG. 20 in the selected cell transistor MTr (step S24). The write shown in FIG. 20 is a write for the case when the cell transistor MTr is close to the source line CELSRC. In the following, it will be referred to as source line-side write.

Then, the controller 5 determines whether the write in the selected cell transistor MTr is over the upper limit (step S25). Step S25 is the same as the step S2 shown in FIG. 13. The upper limit adopted in step S25 is also identical to the upper limit explained in Embodiment 2. When the determination result is NO in step S25, the flow returns to step S24. On the other hand, when the determination result is YES in step S25, the flow goes to step S27. In step S27, the controller 5 determines whether the current value x is over n/2. If the determination result is NO in step S27, the controller 5 refreshes the current value x to x+1 (step S28). Then, the flow returns to step S22, and, for the refreshed current value x, the operation of steps S22, S24 and S25 is repeated. That is, the bit line-side write is carried out in the cell transistor MTr adjacent on the bit line side to the selected cell transistor MTr of the last round. Until the determination result becomes YES in step S27, write in all of the cell transistors MTr nearer the source line CELSRC is carried out repeatedly sequentially from the cell transistor MTr at the end on the source line side towards the bit line BL. In step S27, upon end of write to all of the cell transistors MTr nearer the source line CELSRC, the flow comes to an end. Also, write may be carried out on the bit line side after write on the source line side, a procedure opposite to the flow shown in FIG. 21.

In order to carry out write shown in FIG. 21, the number of the cell transistors MTr connected in series in the memory string MS should be at least 4. With such number, it is possible to carry out the bit line-side write and the source line-side write, and in either the bit line-side write and the source line-side write, it is possible to guarantee the non-selected cell transistors MTr that contribute to the channel boost with a number larger than that of the selected cell transistors MTr.

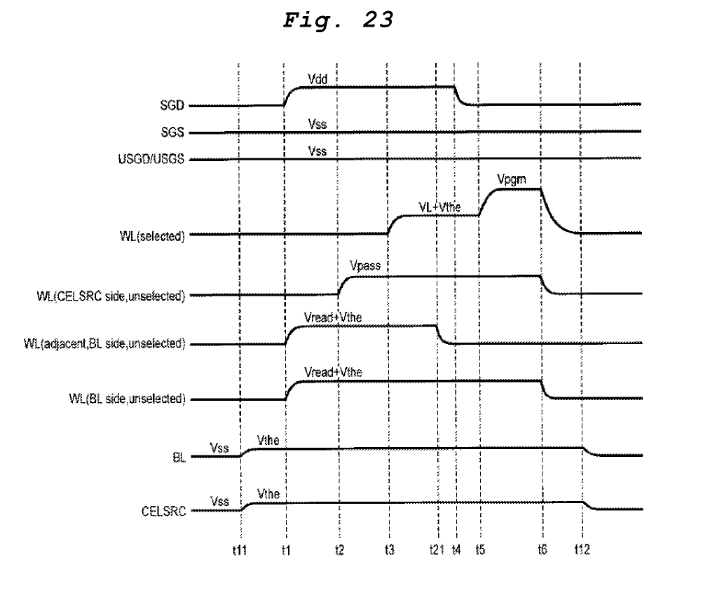

The cell transistor MTr selected before may have a negative threshold voltage. FIG. 22 is a diagram illustrating an example in such case. It shows the state during write related to the fourth example of Embodiment 5. FIG. 23 is a time chart illustrating the voltage during the write shown in FIG. 22. Here, the fundamental principle is the same as that when the transistor SDTr has a negative threshold (FIGS. 16 and 17). That is, the voltage applied on the bit line BL and the source line CELSRC has a negative threshold voltage, and, instead of the voltage Vss when there is no cell transistor MTr selected before (FIGS. 18 and 19), the voltage Vthe is adopted (as a compensating bias). Also, instead of the voltage VL, the voltage applied on the selected word line WL becomes voltage VL+Vthe. Here, the voltage Vthe is the absolute value of the (negative) minimum threshold voltage of the threshold voltage of all of the bit line-side non-selected cell transistors MTr. In addition, instead of the voltage Vread shown in FIG. 19, the voltage Vread+Vthe is applied to all of the bit line-side non-selected word lines WL.

The timing chart shown in FIG. 23 corresponds to the one obtained by mixing FIG. 17 and FIG. 19 and then adding some changes. In the following explanation, only the features different from the drawing will be explained. First of all, at time point t11, the bit line BL and the source line CELSRC are driven from voltage Vss to voltage Vthe. At time point t1, all of the bit line-side non-selected word lines WL are driven to voltage Vread+Vthe. At times t3, t21, t4, and t5, instead of the voltage VL shown in FIG. 19, voltage VL+Vthe is applied to the selected word line WL. At time point t21, all of the bit line-side non-selected word lines (the adjacent bit line-side non-selected word lines) WL adjacent to the selected word line WL are reset from voltage Vread+Vthe to voltage Vss. All of the bit line-side non-selected word lines (the non-adjacent bit line-side non-selected word lines) WL other than the adjacent bit line-side non-selected word lines are kept at Vread+Vthe. The reason is as follows: as all of the bit line-side non-selected word lines WL are set at voltage Vss, the threshold voltage of the cell transistor MTr15 nearest the transistor SDTr is positive, and the threshold voltage of all of the remaining bit line-side non-selected transistors MTr is negative, and, in this case, these non-adjacent bit line-side non-selected transistors MTr are turned on. As a result, the channel potential of the cell source side non-selected transistors MTr is also propagated in the channels of these transistors, so that the boost efficiency decreases. At time point t6 after time point t5, the non-adjacent bit line-side non-selected word lines WL have the voltage returned from the voltage Vread+Vthe to voltage Vss.

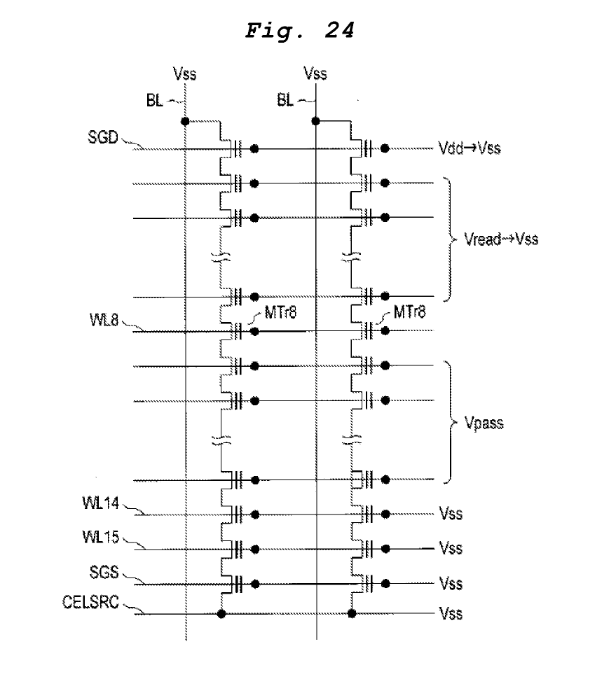

In the explanation, all the examples relate to the case of driving of all of the source side non-selected word lines WL to the voltage Vpass. On the other hand, it is also possible to drive only a portion of the source side non-selected word lines WL to Vpass. FIG. 24 is a diagram illustrating the state during write related to the fifth example of Embodiment 5. As shown in FIG. 24, among all of the source side non-selected word lines WL, some of them near the selected cell transistor MTr are driven to voltage Vpass, while the remaining word lines are kept at voltage Vss. FIG. 24 is a diagram illustrating an example wherein the source side non-selected word lines WL9 to WL13 are driven to Vpass. The number of the word lines is not limited to that in the example shown in FIG. 24. In Embodiment 5, corresponding to which word line WL is selected, the number of the source side non-selected word lines WL varies. Difference in the number of the source side non-selected word lines WL is related to the difference in the number of the cell transistors MTr attributing to the channel boost, and thus related to the difference in the ability of the channel boost. According to the fifth example, independent of the site of the selected word line WL, the number of the source side non-selected word lines WL driven to voltage Vpass is constant. Consequently, the channel boost ability can be kept constant independent of the selected cell transistor MTr.

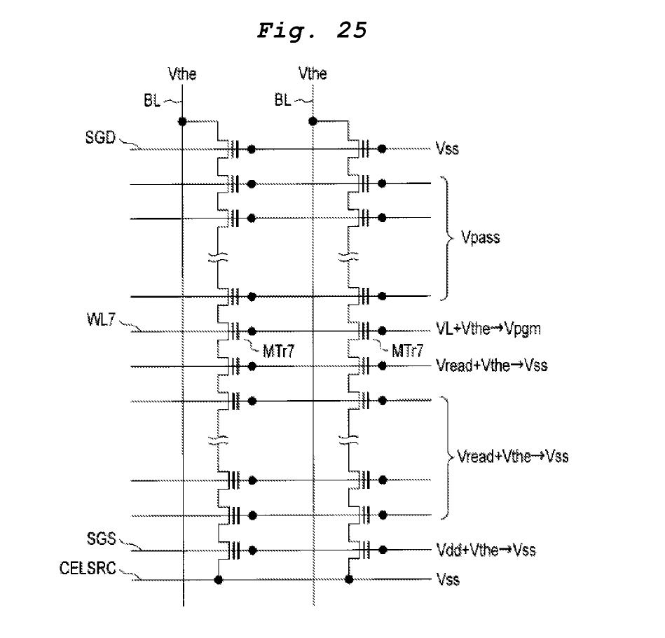

Even in the case of the source line-side write as shown in FIG. 25, the scenario is the same as the bit line-side write. FIG. 25 is a diagram illustrating the state during write related to the sixth example of Embodiment 5. Instead of the select gate line SGD, the select gate line SGS is driven to the voltage Vdd+Vthe, and the select gate line SGD is kept at the voltage Vss. All of the source side non-selected word lines WL are driven from the voltage Vss to the voltage Vread+Vthe. The bit line-side non-selected word lines WL are driven to Vpass.

As explained above, according to Embodiment 5, write of Embodiment 1 is carried out sequentially for the cell transistors from the cell transistor MTr at the end of the memory string MS towards the center of the string. According to this write operation, the same merits as those in Embodiment 1 by exploiting the write of Embodiment 1 can be realized, and, at the same time, the write of Embodiment 1 can also be adopted in the cell transistors MTr other than that at the end of the memory string MS. In addition, after end of the bit line-side write, write of Embodiment 1 is carried out in the same way as above from the cell source side in the cell transistors MTr. By such write, it is possible to carry out write of Embodiment 1 in all of the cell transistors MTr in the memory string MS while keeping a sufficient channel boost. Embodiment 5 may also be combined with Embodiment 2.

### Embodiment 6

In Embodiments 1 to 5, the same data are written in the multiple cell transistors that share the word lines. That is, the same threshold voltage is taken as the target, and the threshold voltage is pulled up. On the other hand, Embodiment 6 relates to write in only the selected cell transistors among the multiple cell transistors that share the word lines.

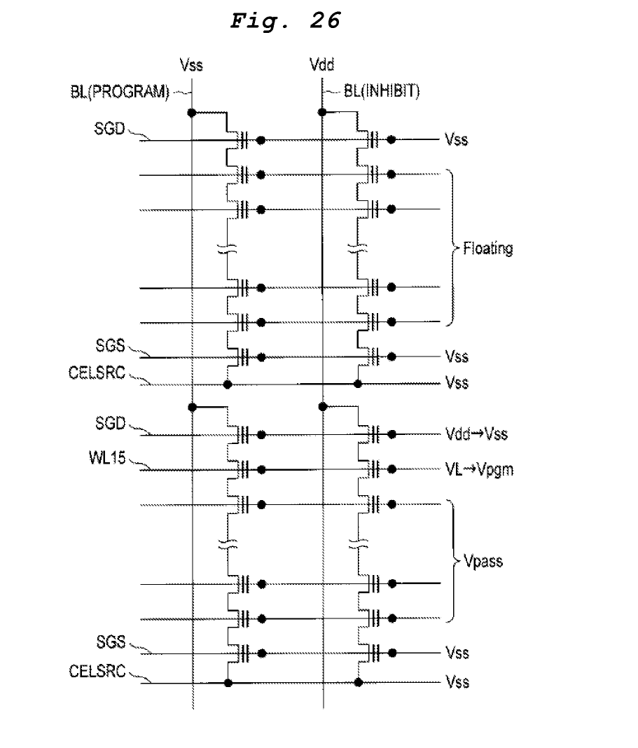

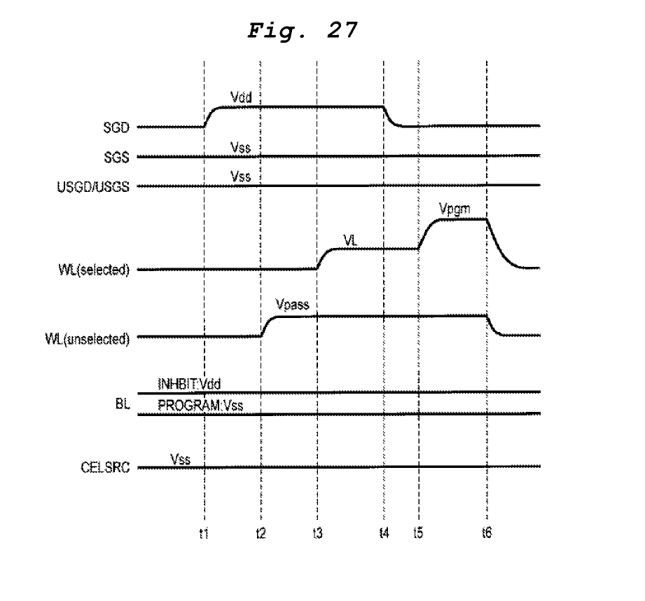

FIG. 26 illustrates the state during write related to Embodiment 6. FIG. 27 is a time chart of the voltage during the write related to Embodiment 6. In Embodiment 6, by performing both the write of Embodiment 1 and formation of the inhibit state using the bit line BL, the program state takes place only in the selected cell transistors among the multiple cell transistors MTr that share the word lines WL. Consequently, as shown in FIG. 26 and FIG. 27, during write, the voltage Vdd is kept on the bit line BL connected to the cell transistors MTr without write among the multiple cell transistors MTr connected with the selected word line WL. The written cell transistors MTr are the same as those in Embodiment 1. As a result of such voltage application, for the transistor SDTr in the memory string MS the same as the cell transistors MTr without write, because the voltage at the bit line BL connected to it is Vdd, the select gate line SGD is kept off during the voltage Vdd. Consequently, the channel is boosted in the cell transistors MTr without write irrelevant to their threshold voltage. In this state, as the voltage Vpgm is applied, the program state is formed only in the prescribed cell transistors among the multiple cell transistors MTr that share the word lines WL. In addition, as in Embodiment 2, by repeating write, only the prescribed cell transistor MTr has the target threshold voltage.

By write according to Embodiment 6, just as in the conventional write operation, it is possible to write the binary data in each of the cell transistors MTr in the selected page, and it is possible to write any of the 4-value data in the prescribed cell transistors MTr. In addition, as the bit line voltage is related to write, write in Embodiment 6 takes only 1 page (1 string) as the write object. Consequently, during write, the selected gate lines SGD, SGS of the non-selected string are kept at voltage Vss. Also, the magnitudes of the voltages Vdd, Vss applied on the bit line BL are restricted by the threshold voltage of the transistor SDTr. That is, it is necessary to ensure that the transistor SDTr can be turned on when the voltage Vdd is applied.

In Embodiment 6, it is possible to make write of data in the page, that is, it is possible to adopt the so-called LM write. In the LM write, the cell transistor MTr has a threshold voltage corresponding to the LM state. In the LM state, in the cell transistors MTr that allow holding of the 2-bit 4-value data, the state has write only for the lower page data.

The explanation relates to an example wherein multiple bit lines BL are connected to one source line CELSRC via memory strings MS, respectively. However, it may also be adopted in the example where one source line CELSRC is set for the various bit lines BL. By adopting these examples in combination, it is possible to write any data in the multiple cell transistors MTr that share the word line WL. The structure where a source line CELSRC is arranged for each bit line BL is described in, e.g., JP-A-2011-204713. The technology disclosed in JP-A-2011-204713 has a constitution wherein the bit lines and the source lines are arranged extending in the same direction, and they are arranged side-by-side and different from each other, and the adjacent one bit line and one source line form a pair. Here, the memory unit MU shown in FIG. 4 in the present specification has an inclination of about 45° with respect to the X-axis and Y-axis on the XY-plane in FIG. 4, and, at the same time, it is connected to a pair of bit line and source line.

As explained above, according to Embodiment 6, both the write in Embodiment 1 and formation of the program state and the inhibit state using the bit line BL are adopted. Due to use of the write of Embodiment 1, the same merits of Embodiment 1 can be obtained, and it is possible to write the data respectively in the selected page.

### Embodiment 7

Embodiment 7 relates to write carried out in parallel to multiple strings and formation of the inhibit state using the bit lines.

Embodiment 3 relates only to the parallel write in multiple strings using the write in Embodiment 1. The write in Embodiment 1 forms the inhibit state using cutoff of the cell transistors MTr. On the other hand, in the write of the prior art, cutoff of the transistor SDTr is used to form the inhibit state. The cutoff of the transistor SDTr requires control of potential of the bit line BL. However, it can realize cutoff with a higher reliability than the cell transistors MTr. Here, in Embodiment 7, both the write adopting Embodiment 1 to multiple strings as in Embodiment 3 and formation of the inhibit state using the bit line BL as in Embodiment 6 are adopted.

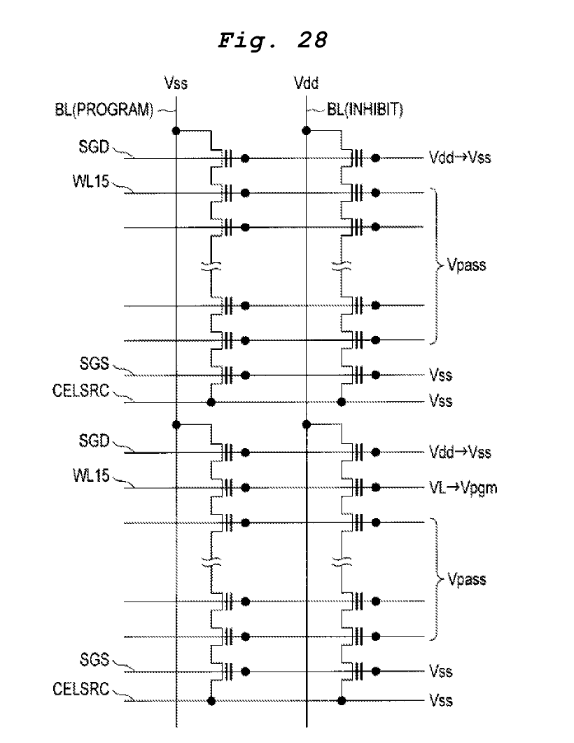

FIG. 28 is a diagram illustrating the state during the write related to Embodiment 7. FIG. 29 is a flow chart of write related to Embodiment 7. As a summary, while Embodiment 3 (FIG. 15) is adopted to carry out parallel write in multiple strings, verify is carried out by read for each bit line BL. For each bit line BL, when end of write in the multiple cell transistors MTr as the write objects connected with the bit line BL is checked by verify, this bit line BL is driven to the voltage Vdd as in Embodiment 6. FIG. 28 shows the state in which one bit line BL has voltage Vss for the program state, and the other bit line BL has a voltage Vdd for the inhibit state. FIG. 29 shows the flow carried out with respect to each bit line BL. FIG. 28 and FIG. 29 illustrate an example of write in the word line WL15.

As shown in FIG. 28 and FIG. 29, first of all, by application of voltage just as in Embodiment 3, write is carried out in parallel in multiple strings (step S31). As a result of write, on the basis of the principle of Embodiment 1, the cell transistors over the target threshold voltage among the multiple selected cell transistors MTr automatically become the inhibit state. Then, the controller 5 carries out verify by read (step S32). In the verify, for each bit line BL, determination is made on whether all of the selected cell transistors (cell transistors sharing the word lines WL) MTr connected to the bit line BL are passed. The controller 5 has a constitution that can carry out such operation.

As a result of the verify, for certain bit line BL, even when only one of all of the selected cell transistors MTr connected to the bit line BL is a failure, the flow returns to step S31. The bit line BL connected to even one cell transistor MTr that fails is kept at voltage Vss in step S31, and the program state is formed for the bit line BL determined to be failed. In this way, just as in Embodiment 2, write is repeated.

On the other hand, in step S32, when it is determined that all of the selected cell transistors MTr are passed, write for the bit line BL ends. More specifically, during the write in the other bit lines BL, the bit line BL determined to be passed is driven to voltage Vdd. In this way, the inhibit state is formed for the bit line BL determined to be passed (such as the bit line BL on the right hand side in FIG. 28). The inhibit state using the voltage of the bit line BL is deeper than the inhibit state by cutoff of the cell transistor MTr having a threshold voltage higher than the read voltage VL. The cell transistors MTr in the deeper inhibit state are protected reliably from formation of the program state.

As explained above, according to Embodiment 7, both the parallel write in the multiple strings according to Embodiment 1 and formation of the program state and inhibit state using the bit line are adopted. By using write of Embodiment 1, the same merits as those of Embodiment 1 can be realized, and, at the same time, the parallel write in the multiple strings can be realized while an even deeper inhibit state is formed using the bit line BL.

### Embodiment 8

Embodiment 8 relates to parallel write in two cell transistors in one memory string.

The write in Embodiment 1 does not contain control of the voltage of the bit line BL. Consequently, the bit line BL and source line CELSRC can be swapped in use, and this feature is exploited to carry out two types of write, that is, the bit line-side write and the source line-side write. In Embodiment 8, these two types of write are carried out in parallel, and write is carried out in parallel to the two cell transistors MTr in one memory string MS.

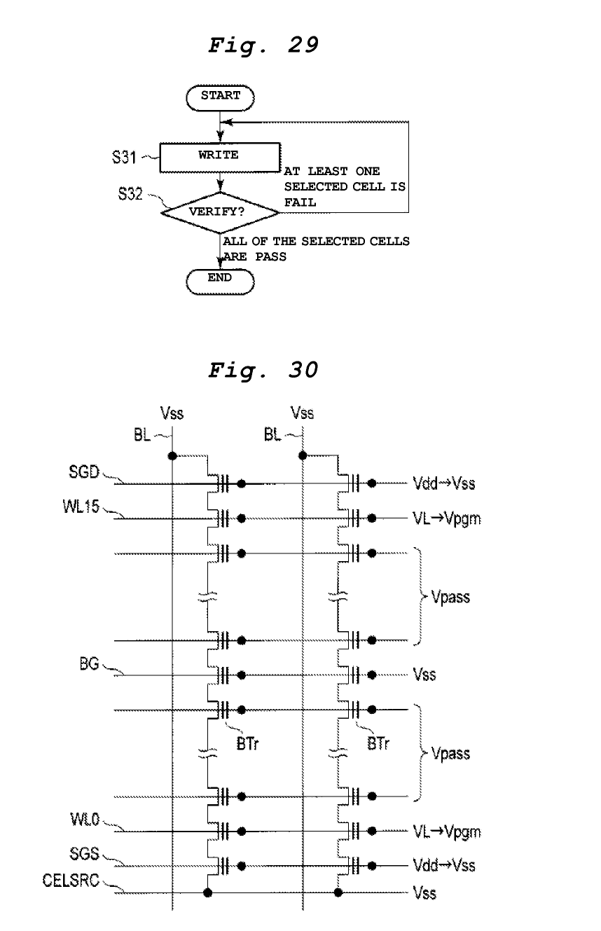

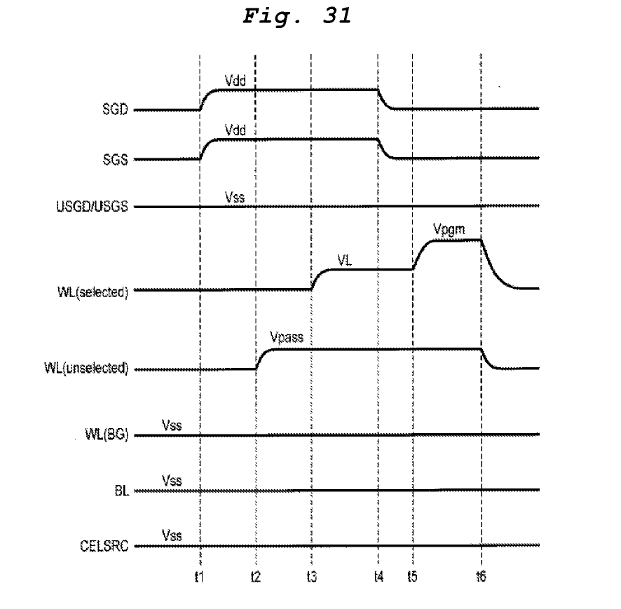

FIG. 30 is a diagram illustrating the state during write related to Embodiment 8. FIG. 31 is a time chart illustrating the voltage during write related to Embodiment 8. FIG. 30 shows an example of write to the cell transistors MTr at the two ends of the memory string MS. During the write, a cell transistor MTr having a positive threshold voltage near the center of the memory string MS is prepared. This is for separating the memory string MS to two portions, that is, the bit line side and the source side. As shown in FIG. 30, as the cell transistor for cutoff, the back gate transistor BTr in the BiCS memory can be used. As shown in FIG. 30 and FIG. 31, during the write, that is, during the time points t1 to t6, the back gate BG of the cell transistor for separation (transistor BTr) is kept on voltage Vss. In this state, the bit line-side write and the source line-side write are carried out in parallel. That is, at time point t1, both the select gate lines SGD, SGS are driven to the voltage Vdd. At time point t3, the two selected word lines WL are driven to verify voltage VL. When different verify voltages VL are applied on the two word lines WL, it is possible to write the different data to two selected cell transistors MTr. Then, at time point t4, both the select gate lines SGD, SGS are reset at voltage Vss. Then, at time point t5, both the two selected word lines WL are driven to the write voltage Vpgm. The other characteristic features are the same as those in Embodiment 1.

In the above explanation, the example has the selected cell transistors MTr located at the two ends of the memory string MS. However, it is also possible to select the cell transistors MTr other than those at the two ends. Consequently, Embodiment 5 is adopted, and the condition shown in explanation of Embodiment 5 is met. That is, for the bit line-side write (or the source line-side write), the bit line-side non-selected cell transistors (or the source side non-selected cell transistors MTr) should have a positive threshold voltage. Also, for the bit line-side write, the number of the non-selected cell transistors between the selected cell transistor MTr and the separating cell transistor MTr should be a number that can boost the channels of these transistors to the voltage Vpass sufficiently. The same is true for the source line-side write, and the non-selected cell transistors contributing to the channel boost should have a sufficient number.

As explained above, according to Embodiment 8, the bit line-side write and the cell source-side write are carried out in parallel by using the write of Embodiment 1. By using the write of Embodiment 1, the same merits as those in Embodiment 1 can be realized, and, at the same time, it is possible to write in parallel the data in the two cell transistors MTr in one memory string MS.

Any of Embodiments 1 to 8 may be combined with the other embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

Structure of the memory cell array 10 is not limited as described above. A memory cell array may have the structure disclosed in U.S. patent application Ser. No. 12/532,030, the entire contents of which are incorporated by reference herein.

What is claimed is:

1. A semiconductor storage device, comprising:
a plurality of cell transistors connected in series;
a first selecting transistor connected to a cell transistor at a first end of the serially connected cell transistors;
a second selecting transistor connected to a cell transistor at a second end of the serially connected cell transistors;
a first wire connected to the first selecting transistor;
a second wire connected to the second selecting transistor; and
a plurality of word lines, each word line connected a respective cell transistor;
wherein the storage device is configured to store information in the cell transistors with a writing process that includes:
applying a first voltage to a gate of the first selecting transistor, and a second voltage lower than the first voltage to a gate of the second selecting transistor;
applying a verify voltage to a selected word line, and a pass voltage to non-selected word lines connected to the cell transistors located between the cell transistor connected to the selected word line and the second selecting transistor;
applying a third voltage lower than the first voltage to the gate of the first selecting transistor; and
applying a program voltage to the selected word line.

2. The semiconductor storage device according to claim 1, wherein:
when the first voltage is applied to the gate of the first selecting transistor, the first selecting transistor is turned on;
when the second voltage is applied to the gate of the second selecting transistor, the second selecting transistor is kept off; and
when the third voltage is applied to the gate of the first selecting transistor, the first selecting transistor is turned off.

3. The semiconductor storage device according to claim 1, wherein the writing process to the cell transistors is repeated for a first number of rounds.

4. The semiconductor storage device according to claim 1, wherein a plurality of the memory strings are connected between the first line and the second line, and the cell transistors in the various memory strings share word lines.

5. The semiconductor storage device according to claim 1, wherein, when the first selecting transistor is turned on, a voltage higher than a negative supply potential is applied to the first line and the second line.

6. The semiconductor storage device according to claim 1, wherein the writing process is performed on the cell transistors starting with the cell transistor nearest the first selecting transistor, and then, in sequence, an adjacent cell transistor closer to the second selecting transistor.

7. The semiconductor storage device according to claim 6, wherein a pass voltage is applied to the non-selected word lines that are connected to the cell transistors closer to the second selecting transistor line than the selected word line.

8. The semiconductor storage device according to claim 1, wherein, during writing process:
the first line is kept at a negative supply potential when writing is performed on a selected cell transistor; and
the first line is kept at a positive potential when writing is not performed on the selected cell transistor.

9. A method of writing information to a semiconductor storage device, the storage device including a plurality of cell transistors connected in series, a first selecting transistor connected to a cell transistor at a first end of the serially connected cell transistors, a second selecting transistor connected to a cell transistor at a second end of the serially connected cell transistors, a first wire connected to the first selecting transistor, a second wire connected to the second selecting transistor, and a plurality of word lines, each word line connected a respective cell transistor, the method comprising:
applying a first voltage to a gate of the first selecting transistor, and a second voltage lower than the first voltage to a gate of the second selecting transistor;
applying a verify voltage to a selected word line, and a pass voltage to non-selected word lines connected to the cell transistors located between the cell transistor connected to the selected word line and the second selecting transistor;
applying a third voltage lower than the first voltage to the gate of the first selecting transistor; and
applying a program voltage to the selected word line.

10. The method of claim 9, wherein:
when the first voltage is applied to the gate of the first selecting transistor, the first selecting transistor is turned on;
when the second voltage is applied to the gate of the second selecting transistor, the second selecting transistor is kept off; and
when the third voltage is applied to the gate of the first selecting transistor, the first selecting transistor is turned off.

11. The method of claim 9, wherein the writing to the cell transistors is repeated for a first number of rounds.

12. The method of claim 9, wherein:
a plurality of the memory strings are connected between the first line and the second line;
the cell transistors in the various memory strings share word lines; and
cell transistors of multiple memory strings are written simultaneously.

13. The method of claim 9, wherein, when the first selecting transistor is turned on, a voltage higher than a negative supply potential is applied to the first line and the second line.

14. The method of claim 9, wherein the writing process is performed on the cell transistors starting with the cell transistor nearest the first selecting transistor, and then, in sequence, an adjacent cell transistor closer to the second selecting transistor.

15. The method of claim 14, wherein a pass voltage is applied to the non-selected word lines which are connected to the cell transistors closer to the second selecting transistor line than the selected word line.

16. The method of claim 9, wherein the first line is kept at a negative supply potential when writing is performed on a selected cell transistor, and the first line is kept at a positive potential when writing is not performed on the selected cell transistor.

17. A method of storing data in a semiconductor storage device, the storage device including a plurality of cell transistors connected in series to form a memory string, a first selecting transistor connected to a first end of the memory string, a second selecting transistor connected to a second end of the memory string, and a plurality of word lines, each word line connected to a respective cell transistor in the memory string, the method comprising:
applying a first voltage to a gate of the first selecting transistor;
selecting a word line connected to a cell transistor to be written with data;
applying a pass voltage to one or more unselected word lines;
applying a verify voltage to the selected word line, then subsequently applying a negative supply potential to the gate of the first selecting transistor; and
applying a program voltage to the selected word line,
wherein:
the first voltage is greater than the pass voltage;
the pass voltage is between the negative supply potential and the program voltage; and
the verify voltage is less than the program voltage.

18. The method of claim 17, wherein steps of the method are repeated a first number of times.

19. The method of claim 17, wherein the serially connected cell transistors are written in sequence starting from the first selecting transistor or the second selecting transistor.

20. The method of claim 17, wherein at least one cell transistor has a negative threshold value, and the method further comprises:
applying a compensating potential to the bit line connected to the at least one cell transistor.
